(19) United States
(12) Patent Application Publication
(10) Pub. No.: US 2026/0293364 A1
(43) Pub. Date: Sep. 24, 2026

(54) AN AVALANCHE PHOTODIODE DEVICE

(71) Applicant: PHLUX TECHNOLOGY LTD, Sheffield (GB)

(72) Inventors: Xiao COLLINS, Sheffield (GB); David ROBBINS, Sheffield (GB); Benjamin WHITE, Sheffield (GB)

(21) Appl. No.: 19/476,298

(22) PCT Filed: Apr. 17, 2024
(86) PCT No.: PCT/GB2024/051003

§ 371 Date: Oct. 17, 2025

(30) Foreign Application Priority Data
Apr. 18, 2023 (GB) 2305698.9
Apr. 18, 2023 (GB) 2305699.7
Apr. 18, 2023 (GB) 2305701.1

(51) Int. Cl. H10F 77/14; H10F 30/225; H10F 77/124

(52) U.S. Cl. CPC H10F 77/147; H10F 30/225; H10F 77/1248

(57) ABSTRACT

The present invention relates to an avalanche photodiode (APD) sub-assembly and an APD device (200). The APD sub-assembly comprising: a substrate (201); a n-type contact layer (203) formed on the substrate (201); a p-type contact layer (202); and an avalanche layer (206) comprising antimony. The avalanche layer (206) is disposed between the n-type contact layer (203) and the p-type contact layer (203). The APD sub-assembly has a multi-stage structure comprising a first stage (207) and a second stage (208). The first stage (207) comprises the p-type contact layer (202) and the second stage (208) comprises the avalanche layer (206). The first stage (207) has a smaller cross-sectional area than the second stage (208), the cross-sectional area being perpendicular to a direction from the substrate (201) to the p-type contact layer (202).

This invention relates to an avalanche photodiode (APD) device. In particular, an APD device comprising an avalanche layer comprising antimony.

### BACKGROUND

Avalanche photodiode (APD) devices have internal gain and are used to improve the sensitivity of optical systems. Example applications include laser range finding; light detection and ranging (LIDAR) systems using time of flight and frequency modulated continuous wave measurements; optical time domain reflectometry; telecommunications and quantum communications and computing. The internal gain of an APD is generated through a process called impact ionisation, whereby charge carriers gain energy in a high electric field and multiply. InGaAs lattice matched to InP has a bandgap energy of 0.75 eV at room temperature and is used as the absorbing layer in a wide range of infrared detectors. However, InGaAs is not suitable for generating avalanche gain as its narrow bandgap generates excessive tunnelling current at the high electric fields required for impact ionisation. In order to minimize tunnelling currents, infrared APDs use a design called a separate absorption and multiplication (SAM)APD. In a SAMAPD a wider bandgap semiconductor is used for avalanche gain, and a separate narrower bandgap semiconductor is used to absorb light.

It is known from GB2591320B to provide a SAMAPD structure comprising an absorption layer comprising InGaAs, InGaAlAs, InGaAsP, or an InGaAs/GaAsSb type-II superlattice and an avalanche layer comprising AlGaAsSb. In an APD, AlGaAsSb has near ideal avalanche multiplication characteristics and yields very low noise APDs. AlGaAsSb based APDs are able to be operated at very high level of avalanche gain while remaining in linear or sub-geiger mode. However, operating an AlGaAsSb based SAMAPD at high gain and low noise requires a highly uniform electric field region within the multiplication region.

The presence of antimony (Sb) in the avalanche layer can result in defects or irregularities when manufacturing the SAMAPD. The defects or irregularities may be caused by different etch rates of Sb containing alloys compared to other semiconductors in the structure or oxidization of antimony containing alloys during wet etching. For example, when wet etching AlGaAsSb based SAMAPDs, different etch rates of the antimony containing alloys compared to non-antimony containing semiconductors may cause sidewalls of the SAMAPD to form an irregular profile. Defects or irregularities in the SAMAPD may create local regions of high electric field (known as hotspots) within the device, cause current leakage and create reliability problems thereby limiting the performance of the device.

It is an object of certain embodiments of the present invention to overcome certain disadvantages associated with the prior art. In particular, embodiments of the present invention may provide an APD with an avalanche layer comprising antimony with improved reliability of manufacturing that is operable at high gain, with low noise.

### BRIEF SUMMARY OF THE DISCLOSURE

In accordance with an aspect of the present invention there is provided an avalanche photodiode (APD) sub-assembly comprising:
a substrate;
a n-type contact layer formed on the substrate;
a p-type contact layer; and
an avalanche layer comprising antimony, the avalanche layer being disposed between the n-type contact layer and the p-type contact layer;
wherein the APD sub-assembly has a multi-stage structure comprising a first stage and a second stage;
wherein the first stage comprises the p-type contact layer and the second stage comprises the avalanche layer; and
wherein the first stage has a smaller cross-sectional area than the second stage, the cross-sectional area being perpendicular to a direction from the substrate to the p-type contact layer.

In certain embodiments, the avalanche layer may comprise AlGaAsSb, InAlAsSb or AlAsSb.

In certain embodiments, the distance between a sidewall of the first stage and a sidewall of the second stage in a direction perpendicular to a direction from the substrate to the n-type contact layer may be at least 15 μm.

In certain embodiments, the avalanche layer may have a thickness of from 100 nm to 1500 nm or from 300 nm to 1000 nm.

In certain embodiments, the APD sub-assembly may comprise a first spacer layer disposed between the avalanche layer and the p-type contact layer. The first spacer layer may comprise a lower portion and an upper portion. The upper portion may have a smaller cross-sectional area than the lower portion. The cross-sectional area may be perpendicular to the direction from the substrate to the p-type contact layer. The lower portion may define an upper boundary of the second stage.

In certain embodiments, the first spacer layer may comprise InP, InAlAs or AlGaAsSb.

In certain embodiments, the first spacer layer may have a thickness of between 250 nm and 4000 nm or the first spacer layer has a thickness of between 50 nm and 200 nm.

In certain embodiments, the ADP sub-assembly may comprise a field control layer disposed between the avalanche layer and the first spacer layer. The field control layer may be p-doped.

The field control layer may comprise InAlAs, InGaAlAs, InP or InGaAsP.

In certain embodiments, the APD sub-assembly may comprise an absorption layer.

The absorption layer may be disposed between the avalanche layer and the p-type contact layer.

The absorption layer may be disposed between the first spacer and the p-type contact layer.

The absorption layer may comprise InGaAlAs, InGaAlAs, InGaAsP, or an InGaAs/GaAsSb type-II superlattice.

In certain embodiments, the APD sub-assembly may comprise a transition portion disposed between the first spacer layer and the absorption layer. The transition portion may comprise a first grading layer of InAlGaAs or InGaAsP and a charge sheet disposed between the first grading layer and the avalanche layer. The charge sheet may have a bandgap between the bandgap of the absorption layer and the bandgap of the avalanche layer.

The charge sheet may comprise InAlAs and/or the second charge sheet may be p-doped.

In certain embodiments, the upper portion of the spacer layer resides within the first stage. In such embodiments, the APD sub-assembly may comprise a second grading layer disposed between the absorption layer and the p-type contact layer.

In certain embodiments, the multi-stage stage structure may comprise a third stage disposed between the second stage and the first stage. The third stage may have a smaller cross-sectional area than the first stage and a larger cross-sectional area than the second stage. The cross-sectional areas may be perpendicular to the direction from the substrate to the p-type contact layer. The third stage may comprise the upper portion of the first spacer layer and the absorption layer.

The APD sub-assembly may comprise a second spacer layer disposed between the absorption layer and the p-type contact layer. The second spacer layer may comprise an upper portion and a lower portion. The upper portion may have a smaller cross-sectional area than the lower portion the cross-sectional area being perpendicular to the direction from the substrate to the p-type contact layer. The third stage may comprise the lower portion and the first stage may comprise the upper portion.

The second spacer layer may comprise InP, InAlAs or AlGaAsSb.

In certain embodiments, the APD sub-assembly may comprise a graded cladding layer within the first stage, disposed between the second spacer and the p-type contact. The graded cladding layer may have a graded doping which increases in a direction from the n-type contact layer to p-type contact layer from highly p-doped to intrinsic.

In certain embodiments, the p-type contact layer may comprise InGaAs, InP, InGaAsP, InAlAs or InGaAlAs.

In certain embodiments, the n-type contact layer may comprises InGaAs, InP, InGaAsP, InAlAs or InGaAlAs and/or the n-type contact layer may be n-doped with silicon or tellurium.

In certain embodiments, wherein the multi-stage structure may be a multi-stage mesa structure, the first stage may be a first mesa and the second stage may be a second mesa.

In certain embodiments, the third stage may be a third mesa.

In certain embodiments, the multi-stage structure may comprise a stepped structure, wherein the first stage provides a first step and the second stage provides a second step.

In certain embodiments, the third stage may provide a third step.

In accordance with an aspect of the present invention there is provided an APD device comprising the above-described APD sub-assembly.

In certain embodiments, the APD device may comprise an electrode formed on each of the p-type contact layer and the n-type contact layer.

### BRIEF DESCRIPTION OF THE DRAWINGS

Embodiments of the invention are further described hereinafter with reference to the accompanying drawings, in which:

FIG. 1 schematically shows a cross-section of an avalanche photodiode device according to an embodiment of the present invention;

FIG. 2 shows a graph indicating the dark current of an avalanche photodiode of the type described in FIG. 1;

FIG. 3 schematically shows a cross-section of an avalanche photodiode device according to an embodiment of the present invention;

FIG. 4 schematically shows a cross-section of an avalanche photodiode device according to an embodiment of the present invention; and

FIG. 5 schematically shows a cross-section of an avalanche photodiode device according to an embodiment of the present invention;

FIG. 6 shows a graph indicating the electric field in the avalanche photodiode of FIG. 5;

FIG. 7 shows a graph of the concentration of zinc across the avalanche photodiode of FIG. 5;

FIG. 8 schematically shows a cross-section of an avalanche photodiode device according to an embodiment of the present invention;

FIGS. 9 to 16 schematically show stages of an avalanche photodiode device according to an embodiment of the present invention during a method of manufacture.

### DETAILED DESCRIPTION

Throughout the present specification, the terms avalanche and multiplication are used interchangeably (for example, “avalanche layer” is synonymous with “multiplication layer”).

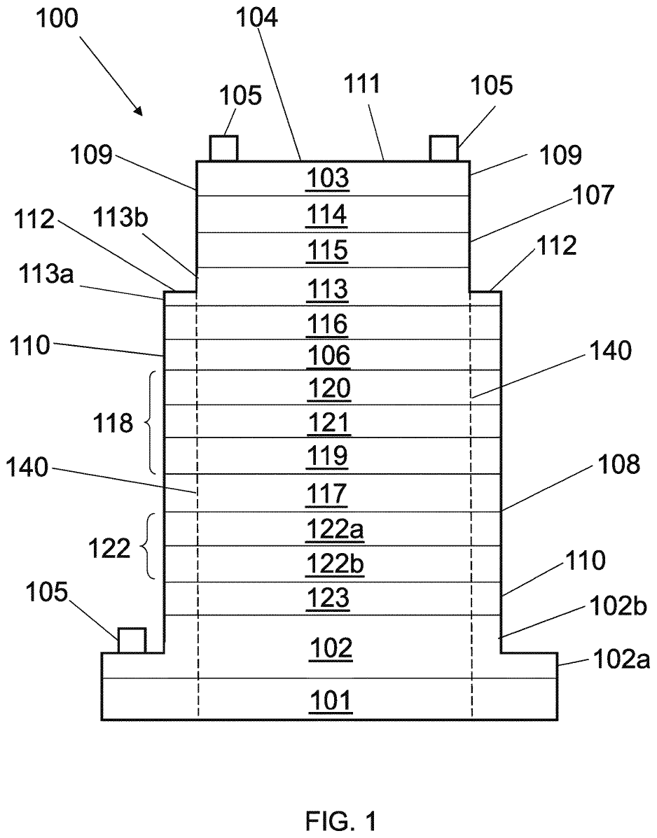

In one embodiment, shown in FIG. 1, there is provided an SAMAPD device 100. The SAMAPD device 100 comprises a substrate 101 and a p-type contact layer 102 formed on the substrate 101. The SAMAPD device 100 also comprises an n-type contact layer 103. As shown in FIG. 1, the device 100 is in an n-i-p configuration as the p-type contact layer 102 is grown on the substrate 101. As such, the n-type contact layer 103 may form an external layer 104 of the device 100. In the embodiment shown in FIG. 1, the substrate 101 may comprise InP. In certain embodiments, any semiconductor materials within the device 100 (i.e. disposed on the substrate 101) may be lattice matched to InP. In the embodiment shown in FIG. 1, the p-type contact layer 102 may comprise InAlAs. In alternative embodiments, the p-type contact layer 102 may comprise InGaAs, InP, InGaAsP or InGaAlAs. The p-type contact layer 102 is p-doped. The p-type contact layer 102 may be heavily doped. In certain embodiments, the p-type contact layer 102 may be p-doped at a concentration from approximately 1.0×10¹⁸ cm⁻³ to approximately 5.0×10¹⁹ cm⁻³. The p-type contact layer 102 may have a thickness from approximately 100 nm to approximately 1000 nm. For the embodiment shown in FIG. 1, the thickness of each layer in the device 100 is measured in a direction from the substrate 101 to the n-type contact layer 103. The thicknesses of the layers in FIG. 1 are not shown to scale. In the embodiment shown in FIG. 1, the n-type contact layer 103 may comprise InGaAs. In alternative embodiments, the n-type contact layer 103 may comprise InP, InGaAsP, InAlAs or InGaAlAs. The n-type contact layer 103 is n-doped.. The n-type contact layer 103 may be heavily doped. In certain embodiments, the n-type contact layer 103 may be n-doped at a concentration from approximately 1.0×10¹⁸ cm⁻³ to approximately 5.0×10¹⁹ cm⁻³. The n-type contact layer 103 may have a thickness from approximately 30 nm to approximately 100 nm. As shown in FIG. 1, one or more electrodes 105 may be provided on each of the p-type contact layer 102 and the n-type contact layer 103. In the embodiment in FIG. 1, one electrode is provided on each of the p-type contact layer 102 and the n-type contact layer 103. The electrode 105 provided on the n-type contact layer 103 is in the shape of a ring. Therefore, the cross-section of the device 100 shown FIG. 1 illustrates two parts of a single ring-shaped electrode 105.

The device 100 comprises an avalanche layer 106 comprising antimony (Sb). The avalanche layer 106 is disposed between the n-type contact layer 103 and the p-type contact layer 102. The avalanche layer 106 may be intrinsic. The avalanche layer 106 may have a thickness between 75 nm to 2000 nm. In the embodiment shown in FIG. 1, the avalanche layer 106 may comprise AlGaAsSb. In certain embodiments, the avalanche layer 106 may comprise AlₓGa₁₋ₓAs_{y}Sb_{1-y}, where x is between 0.4 and 1.0 inclusive and optionally between 0.85 and 1.0 inclusive. In certain embodiments, y may be chosen to lattice match the avalanche layer 106 to an InP substrate 101. In certain embodiments, the avalanche layer 106 may comprise AlₓGa₁₋ₓAs_{y}Sb_{1-y}, where x is 0.85 and y is 0.56. In alternative embodiments, the avalanche layer 106 may instead comprise InAlAsSb or AlAsSb.

As shown in FIG. 1, the SAMAPD device 100 has a multi-stage structure. The multi-stage structure comprises a first stage 107 and a second stage 108. The first stage 107 comprises the n-type contact layer 103 and the second stage 108 comprises the avalanche layer 106. As shown in the embodiment in FIG. 1, the first stage 107 may be positioned centrally on the second stage 108. The second stage 108 may be positioned centrally relative to the substrate 101. As shown in the embodiment in FIG. 1, the first stage 107 comprises a sidewall 109 and the second stage 108 comprises a sidewall 110. The sidewall 109 of the first stage may extend in a direction from the second stage 108 towards an upper surface 111 of the device 100. The sidewall 110 of the second stage 108 may extend in a direction from the substrate 101 towards the first stage 107. As shown in FIG. 1, the layers in the first and second stages 107, 108 each extend to the respective sidewall 109, 110 of the stage 107, 108. Whilst the embodiment shown in FIG. 1 comprises two stages, in alternative embodiments the multi-stage structure may comprise two, three or more stages.

The first stage 107 has a smaller cross-sectional area than the second stage 108 where the cross-sectional area is defined as being perpendicular to a direction from the substrate 101 to the n-type contact layer 103. Therefore, the width of the n-type contact layer 103 is smaller than the width of the avalanche layer 106. As shown in FIG. 1, the layers in the first stage 107 have substantially the same cross-sectional area as each other and the layers in the second stage 108 have substantially the same cross-sectional area as each other.

The multi-stage structure ensures that, during use, the region of the device 100 having a high electric field in the avalanche layer 106 is confined to the area beneath the n-type contact layer 103 as shown by the area between the dashed lines 140 in FIG. 1. The high electric field region does not extend to the sidewalls 110 of the second stage 108. Consequently, only a low electric field extends across the external surfaces (i.e. the sidewall) of the avalanche layer 106. As such, the effect of any irregularities in the sidewalls 109, 110 of the device 100 caused by manufacturing on the performance of the device 100 is reduced and hotspots are not formed (or are at least reduced) at irregularities in the sidewalls 109, 110. Thus, the multi-stage structure produces a device 100 having improved performance and reliability.

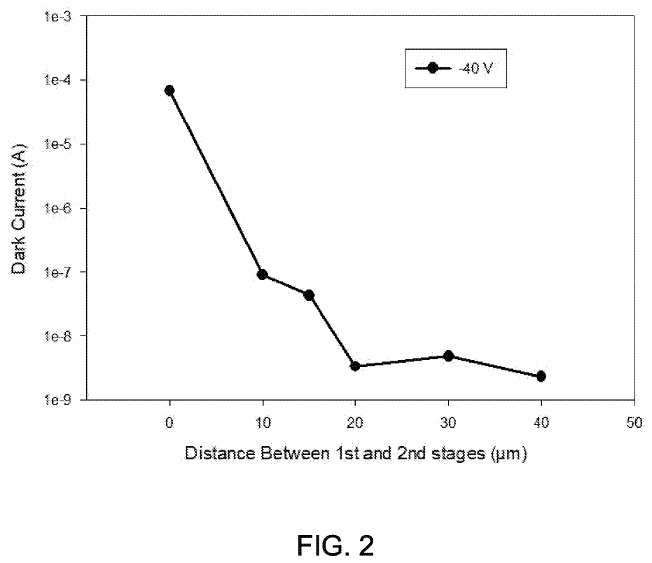

In certain embodiments, a distance between a sidewall 109 of the first stage 107 and a sidewall 110 of the second stage 108 in a direction perpendicular to the direction from the substrate 101 to the n-type contact layer 103 is between 5 μm and 100 μm. FIG. 2 shows a graph of dark current values for different distances between the sidewalls 109, 110 of the first and second stages 107, 108 in a direction perpendicular to the direction from the substrate 101 to the n-type contact layer 103. The dark current provides an indication of the performance of the device 100 and smaller dark current values indicate an improved performance. The value of the dark current at a distance of 0 μm demonstrates the performance of a device that has only single stage. That is, if the n-type contact layer 103 and the avalanche layer 106 had the same cross-sectional area in a direction perpendicular to the direction from the substrate 101 to the n-type contact layer 103. As shown in FIG. 2, providing a first and second stage 107, 108 in the device 100 improves its performance compared to a device with only a single stage. In certain embodiments the distance between the sidewall 109 of the first stage 107 and the sidewall 110 of the second stage 108 may be at least 15 μm. At such distances, the high electric field region is sufficiently far from the sidewalls of the avalanche layer 106 that the risk of hotspots forming at the sidewalls of the avalanche layer 106 due to irregularities is significantly reduced and the tolerance of the device 100 to imperfections is further improved compared to devices in which the distance is less than 15 μm. In certain embodiments the distance between the sidewall 109 of the first stage 107 and the sidewall 110 of the second stage 108 may be at least 20 μm. As shown in FIG. 2, the performance of the device 100 may be considered to be optimal when the distance is at least 20 μm. In certain embodiments the distance between the sidewall 109 of the first stage 107 and the sidewall 110 of the second stage 108 may be 30 μm or less to limit the size and capacitance of the device.

In the non-limiting specific embodiment shown in FIG. 1, the multi-stage structure is a multi-stage mesa structure. The first stage 107 is a first mesa and the second stage 108 is a second mesa.

As shown in FIG, 1 the multi-stage structure may be a stepped structure. The first stage 107 providing a first step and the second stage 108 providing a second step. The first step may be relative to the second stage 108. The second step may be relative to the substrate 101. That is, the second step has a smaller cross-sectional area than the substrate 101, where the cross-sectional area is defined as being perpendicular to a direction from the substrate 101 to the n-type contact layer 103. As shown in the embodiment in FIG. 1, each step may have sidewalls 109, 110 that are substantially perpendicular to the substrate 101. Each step may have an upper surface 111, 112 that is substantially parallel to the substrate 101.

In certain non-limiting embodiments, each of the layers within the device 100 may have a substantially circular cross-section, where the cross-section is in a direction perpendicular to the direction from the substrate 101 to the n-type contact layer 103. Therefore, each of the first stage 107 and the second stage 108 may be substantially cylindrical in shape. However, the invention is not limited to each layer of the device 100 having a substantially circular cross-section. Each layer may have any suitable cross-section. In certain embodiments, each layer may have a substantially rectangular or square cross-section where each corner of the rectangle or square may be rounded.

The inventors found that using a multi-stage structure in combination with an avalanche layer 106 comprising antimony in an SAMAPD device 100 produced unexpected synergistic advantages due to low noise characteristics and wide band gap of the avalanche layer 106. The properties of an antimony based avalanche layer 106 enable a greater thickness to be used for the avalanche layer 106 than in other known devices which has beneficial consequences in the multi-stage structure. A thick antimony avalanche layer may make the device 100 less sensitive to voltage during use. A thick avalanche layer 106 may significantly reduce the peak electric field across the avalanche region that is needed for avalanche gain. Therefore, the build-up of gain with voltage is slower so that the device is less sensitive to voltage and the peak electric field within any hotspots in the device 100 is reduced. As such, the effect of any imperfections in the device 100 on its performance is reduced. In certain embodiments, the avalanche layer 106 may have a thickness of between 300 to 1000 nm.

The device 100 comprises an APD sub-assembly. The APD sub-assembly may comprise a sub-set of the features of the device 100 shown in FIG. 1. For the embodiment shown in FIG. 1, the APD sub-assembly comprises the substrate 101, the p-type contact layer 102 formed on the substrate 101 and the n-type contact layer 103. The sub-assembly also comprises the avalanche layer 106 comprising antimony that is disposed between the p-type contact layer 102 and the n-type contact layer 103. The APD sub-assembly has the multi-stage structure comprising the first stage 107 comprising the n-type contact layer 103 and the second stage 108 comprising the avalanche layer 106. As described above, the first stage 107 has a smaller cross-sectional area than the second stage 108, the cross-sectional area being perpendicular to a direction from the substrate 101 to the n-type contact layer 103. As such, the APD sub-assembly is a constituent part of the device 100. The device 100 may comprise further features in addition to the APD sub-assembly. The APD sub-assembly may optionally comprise one or more additional features of the device 100 that is shown in and described with reference to FIG. 1.

As shown in the embodiment in FIG. 1, the device 100 may comprise a spacer layer 113. The spacer layer 113 may be included in the sub-assembly. The spacer layer 113 may be disposed between the avalanche layer 106 and the n-type contact layer 103. The spacer layer 113 does not comprise antimony. The spacer layer 113 may be intrinsic. The spacer layer 113 may have a thickness between 50 nm and 4000 nm. As shown in FIG. 1, the spacer layer 113 comprises a lower portion 113a which resides within the second stage 108 and an upper portion 113b which resides within the first stage 107. As such, the second stage 108 may comprise the lower portion 113a and the first stage 107 may comprise the upper portion 113b. The upper portion 113b therefore has a smaller cross-sectional area that the upper portion 113b, where the cross-sectional area is measured in a direction perpendicular to the direction from the substrate to the n-type contact layer.

As shown in FIG. 1, the first stage 107 begins within the spacer layer 113. Therefore, when manufacturing the device 100, the device 100 may advantageously be etched so that the transition between the first and second stages 107, 108 occurs within the spacer layer 113. The transition between the first and second stages 107, 108 may occur at any point within the spacer layer 113. This may improve the ease of manufacturing as there is no requirement for the transition between the first and second stages 107, 108 to occur at a boundary between two different layers in the device 100 which may constrain the choice of materials in the device 100. Ending the second stage within the spacer layer 113 rather than at the avalanche layer 106 may also enable surface leakage to be reduced.

Additionally, the lower portion 113a of the spacer layer 113 defines an upper boundary of the second stage 108. As shown in FIG. 1, the lower portion of the spacer layer 113 provides an upper surface 112 of the second stage 108 and ensures that the sidewalls of the avalanche layer 106 are the only external surfaces of the avalanche layer 106. This is advantageous because an avalanche layer 106 comprising antimony may oxidise heavily when used as an etch stop during wet etching. Such oxidization may create irregularities in the device 100 and lead to hotspots forming during use. The spacer layer 113, which does not comprise antimony, may help to create a uniform electric field across the avalanche layer 106 in the second stage 108 and confines the peak electric field away from the external surfaces of the device 100. As only a low electric field extends across the external surfaces of the avalanche layer 106, the spacer layer 113 may improve the tolerance of the device 100 to irregularities and defects from manufacture.

In certain embodiments, the spacer layer 113 may also reduce the capacitance of the device 100 thereby improving the performance of the device 100. The spacer layer 113 may achieve this by increasing the thickness of the device 100. This may be most beneficial when the device 100 is used in low speed applications such as LIDAR. In certain embodiments, the spacer layer 113 may have a thickness of between 250 nm and 4000 nm to reduce the capacitance of the device 100. However, when the device 100 is used in high speed applications, such as telecommunications, the reduction in capacitance from a thick spacer layer 113 may be less important that the speed of the device is capable. Therefore, in certain embodiments, the spacer layer 113 may have a thickness of between 50 to 250 nm.

In the embodiment shown in FIG. 1, the spacer layer 113 may comprise InAlAs. In alternative embodiments, the spacer layer 113 may comprise InP.

The device 100 may comprise one or more additional layers positioned between the spacer layer 113 and the n-type contact layer 103. These layers may be in the first stage 107 of the multi-stage structure as shown in FIG. 1.

The device 100 may comprise a first cladding layer 114 on which the n-type contact layer 103 is formed. The APD sub-assembly may comprise the first cladding layer 114. The first cladding layer 114 may be disposed between the upper portion 113b of the spacer layer 113 and the n-type contact layer 103. The first stage may comprise the first cladding layer 114. The first cladding layer 114 may be n-doped. The first cladding layer 114 may be heavily doped. In certain embodiments, the first cladding layer 114 may be n-doped with a concentration from approximately 1.0×10¹⁷ cm⁻³ to approximately 5.0×10¹⁹ cm⁻³. The first cladding layer 114 may be doped with silicon or tellurium. Using silicon or tellurium as an n-dopant in the device 100 is advantageous because the dopants do not significantly move or diffuse through layers in the device during manufacture. The first cladding layer 114 may have a thickness from approximately 50 nm to approximately 500 nm.

The device 100 may comprise a graded cladding layer 115 between the spacer layer 113 and the n-type contact layer 103. The APD sub-assembly may comprise the graded cladding layer 115. The graded cladding layer 115 may be formed on the upper portion 113b of the spacer layer 113. The graded cladding layer 115 may therefore be disposed between the spacer layer 113 and the first cladding layer 114. The first stage 107 may therefore comprise the graded cladding layer 115. The graded cladding layer 115 may be n-doped. The concentration or level of the dopant within the graded cladding layer 115 may increase in a direction from the substrate 101 to the n-type contact layer 103. In certain embodiments, the concentration of the dopant may increase from 1.0×10¹⁶ cm⁻³ to 1.0×10¹⁸ cm⁻³. In certain embodiments, the concentration of the dopant may increase to or towards that of the first cladding layer 114. The graded cladding layer 115 may be doped with silicon or tellurium. In the embodiment shown in FIG. 1, the graded cladding layer 115 may comprise InAlAs. In alternative embodiments, the graded cladding layer 115 may comprise InP, InGaAlAs or InGaAsP. The graded cladding layer 115 may have a thickness from approximately 50 nm to approximately 500 nm.

In certain embodiments, the doping of the graded cladding layer 115 may be graded so that the concentration of the dopant is substantially the same as that in one or both of the adjacent layers in the device 100 at the interface between the layers. The graded cladding layer 115 may be substantially intrinsic adjacent to the interface between the spacer layer 113 and the graded cladding layer 115. The concentration of the dopant in the graded cladding layer 115 may be substantially the same as that in the first cladding layer 114 adjacent to the interface between the graded cladding layer 115 and the first cladding layer 114. Grading the graded cladding layer 115 in this way may help to further reduce the occurrence of hotspots in the device 100 during use by reducing abrupt changes in grading.

Therefore, as shown in the embodiment to FIG. 1, the device 100 may comprise a first cladding layer 114 and a graded cladding layer positioned between the spacer layer 113 and the n-type contact layer 103 in the first stage 107. However, the invention is not limited to the specific layers or order of layers shown in FIG. 1.

The device 100 may comprise one or more additional layers positioned between the p-type contact layer 102 and the spacer layer 113 as shown in FIG. 1. These layers may be in the second stage 108 of the multi-stage structure.

The device 100 may comprise a field control layer 116. The APD sub-assembly may comprise the field control layer 116. The field control layer 116 may be disposed between the avalanche layer 106 and the spacer layer 113. The second stage 108 may therefore comprise the field control layer 116. The field control layer 116 may be disposed on the opposing side of the spacer layer 113 to the graded first cladding layer 114. The field control layer may be n-doped. The field control layer 116 may be n-doped with a concentration from approximately 1.0×10¹⁷ cm⁻³ to approximately 1.0×10¹⁸ cm⁻³. The field control layer 116 may be n-doped with silicon or tellurium. The field control layer 116 may not comprise antimony. Therefore, in a similar manner to the spacer layer 113, the field control layer 116 may further help reduce the risk of oxidization to the avalanche layer 106 during manufacture using wet etching. In the embodiment shown in FIG. 1, the field control layer 116 may comprise InAlAs. In alternative embodiments, the field control layer 116 may comprise InGaAlAs, InP or InGaAsP. The field control layer 116 may have a thickness from approximately 60 nm to approximately 300 nm.

As described above, the spacer layer 113 may reduce the capacitance of the device 100 thereby improving the performance of the device 100. This effect of the spacer layer 113 may be enhanced by positioning the intrinsic spacer layer 113 between the n-doped graded cladding layer 115 and the n-doped field control layer 116 where the n-dopant is selected so that it does not significantly move or diffuse through layers in the device 100 during manufacture.

As shown in the embodiment in FIG. 1, the device 100 may comprise an absorption layer 117 disposed between the p-type contact layer 102 and the avalanche layer 106. The APD sub-assembly may comprise the absorption layer 117. The second stage may therefore comprise the absorption layer 117. In the embodiment shown in FIG. 1, the absorption layer 117 may comprise InGaAs. In alternative embodiments, the absorption layer 117 may comprise InGaAlAs, InGaAsP, GaAsSb or an InGaAs/GaAsSb type-II superlattice. In certain embodiments, the absorption layer 117 may be intrinsic. The absorption layer 117 may have a thickness from approximately 500 nm to approximately 2500 nm.

The device 100 may comprise a transition portion 118 disposed between the absorption layer 117 and the avalanche layer 106. The APD sub-assembly may comprise the transition portion 118. As shown in FIG. 1, the second stage 108 may comprise the transition portion 118. The transition portion 118 may comprise a first grading layer 119 and a charge sheet 120. The charge sheet 120 may be disposed between the first grading layer 119 and the avalanche layer 106. The charge sheet 120 may have a bandgap between the bandgap of the absorption layer 117 and the bandgap of the avalanche layer 106.

In the embodiment of FIG. 1, the avalanche layer 106 which comprises AlGaAsSb has a wide bandgap whereas the absorption layer 117 comprising InGaAs has a narrow bandgap. The effect of the charge sheet 120 is that the electric field profile of the SAMAPD device 100 is altered such that the electrons predominantly populate the X valleys. As such, under operation, most electrons populate the band structure zone with minimal band offset relative to the avalanche and absorption layers 106, 117. The charge sheet 120 may be made of a wider bandgap material relative to the absorption layer 117, and may be used to increase the electric field to a suitable value to ensure that electrons are predominantly in X valleys, whilst minimizing tunnelling current. The charge sheet 120 therefore improves the transport of charge carriers into the avalanche layer 106.

In certain embodiments, the charge sheet 120 may be p-doped. In certain embodiments, the charge sheet 120 may be p-doped at a concentration between 1×10¹⁷ cm⁻³ and 1×10¹⁸ cm⁻³, and optionally between 1×10¹⁷ cm⁻³ and 5×10¹⁷ cm⁻³. In certain embodiments, the charge sheet 120 may have a thickness between 40 nm and 300 nm. In the embodiment of FIG. 1, the charge sheet 120 may comprise InAlAs. In alternative embodiments, the charge sheet 120 may comprise InP.

In certain embodiments, the first grading layer 119 may have a constant bandgap across its thickness. In the embodiment shown in FIG. 1, the first grading layer 119 may comprise AlGaInAs. In alternative embodiments, the first grading layer 119 may comprise InGaAsP. The first grading layer 119 may be intrinsic. The first grading layer 119 may have a thickness from approximately 25 nm to approximately 50 nm.

As shown in the embodiment in FIG. 1, the transition portion 118 may comprise a second grading layer 121 disposed between the first grading layer 119 and the charge sheet 120. In certain embodiments, the second grading layer 121 may have a constant bandgap across its thickness. The second grading layer 121 may comprise AlGaInAs. The second grading layer 121 may be intrinsic. The second grading layer 121 may have a thickness from approximately 25 nm to approximately 50 nm. The second grading layer 121 has a different bandgap to the first grading layer 119. The second grading layer 121 may have a bandgap between the bandgap of the first grading layer 119 and the avalanche layer 106.

Between the p-type contact layer 102 and the absorption layer 117, the device 100 may comprise a third grading layer 122. The APD sub-assembly may comprise the third grading layer 122. As shown in the embodiment in FIG. 1, the second stage 108 may comprise the third grading layer 122. The third grading layer 122 may be intrinsic. As shown in the embodiment in FIG. 1, the third grading layer 122 may comprise two discrete layers. Each layer having a different bandgap. The second layer 122b of the third grading layer 122 may have a bandgap between the bandgap of the first layer 122a of the third grading layer 122 and the absorption layer 117. The third grading layer 122 may comprise a first layer 122a and a second layer 122b. The second layer 122b may be disposed between the first layer 122a and the absorption layer 117. The second layer 122b may be formed on the first layer 122a. The absorption layer 117 may be formed on the second layer 122b. Each layer in the third grading layer 122 may comprise AlGaInAs. The third grading layer 122 may have a thickness from approximately 25 nm to approximately 50 nm. Each of the first and second layers 122 a, 122 b of the third grading layer 122 may have the same thickness as one another. As such, the first and second layers 122a, 122b of the third grading layer 122 may each have a thickness of 25 nm.

The device may comprise a second cladding layer 123. The APD sub-assembly may comprise the second cladding layer 123. The second cladding layer 123 may be formed on the p-type contact. The second cladding layer 123 may be disposed between the p-type contact layer and the third grading layer. The third grading layer may be formed on the second cladding layer 123. The second cladding layer 123 may be p-doped. The second cladding layer 123 may be p-doped with a concentration from approximately 1.0×10¹⁷ cm⁻³ to approximately 5.0×10¹⁸ cm⁻³. The second cladding layer 123 may have a thickness from approximately 50 nm to approximately 300 nm.

Therefore, as shown in the embodiment in FIG. 1, the device 100 may comprise a second cladding layer 123, a third grading layer 122, an absorption layer 117, a first grading layer 119, a second grading layer 121, a charge sheet 120, an avalanche layer 106 and a field control layer 116 positioned between the p-type contact layer 102 and the spacer layer 113 in the second stage 108. However, the invention is not limited to the specific layers or order of layers shown in FIG. 1.

In the embodiment shown in FIG. 1, the p-type contact layer 102 may comprise an upper portion 102b and a lower portion 102a as shown in the embodiment of FIG. 1. The second cladding layer 123 may be formed on the upper portion 102b of the p-type contact layer 102. The lower portion 102a of the p-type contact layer 102 may be adjacent to the substrate 101. The second stage 108 of the multi-stage structure may comprise the upper portion 102b of the p-type contact layer 102. The upper portion 102b of the p-type contact layer 102 may have a smaller cross-sectional area than both the lower portion 102a of the p-type contact layer 102 and the substrate 101, where the cross-sectional area is defined as being perpendicular to a direction from the substrate 101 to the n-type contact layer 103. As such, the lower portion 102a of the p-type contact layer 102 may not reside with the second stage 108 of the device. The second stage 108 may therefore begin within the p-type contact layer 102. The lower portion 102b of the p-type contact layer 102 may have substantially the same cross-sectional area as the substrate 101. As shown in FIG. 1, one or more electrodes 105 may be formed on the lower portion 102a of the p-type contact layer 102. In alternative embodiments, the p-type contact layer 102 may have a uniform cross-sectional area, where the cross-sectional area is defined as being perpendicular to a direction from the substrate 101 to the n-type contact layer 103. The cross-sectional area of the p-type contact layer 102 may be larger than that of the second stage 108. Therefore, the second stage 108 may not comprise the p-type contact layer 102.

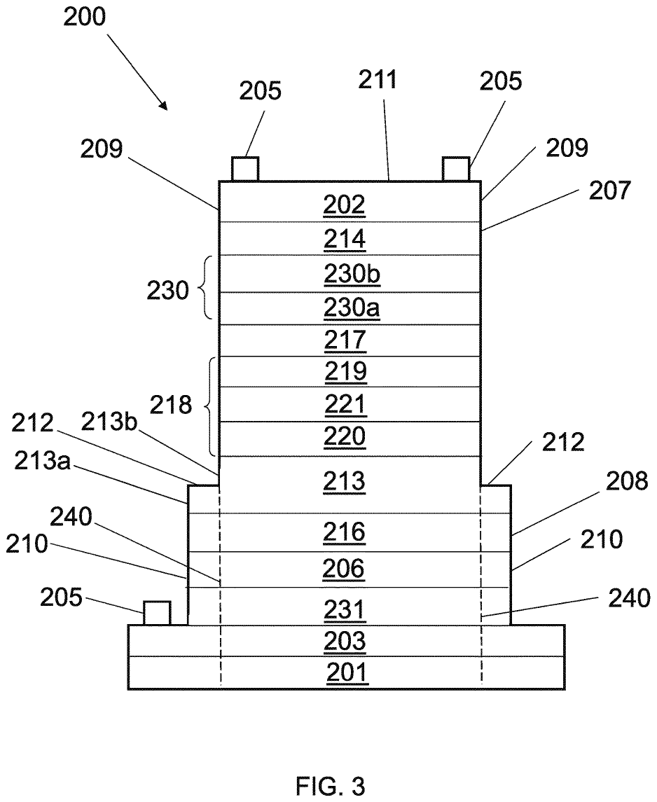

In another embodiment, shown in FIG. 3, there is provided an SAMAPD device 200. The SAMAPD device 200 comprises a substrate 201 and an n-type contact layer 203 formed on the substrate 201. The SAMAPD device 200 also comprises a p-type contact layer 202. As shown in FIG. 3, the device 200 is in a p-i-n configuration as the n-type contact layer 203 is grown on the substrate 201. As such, the p-type contact layer 202 may form an external layer of the device 200. In the embodiment shown in FIG. 3, the substrate 201 may comprise InP. In certain embodiments, any semiconductor materials within the device 200 (i.e. disposed on the substrate 201) may be lattice matched to InP. In the embodiment shown in FIG. 3, the n-type contact layer 203 may comprise InAlAs. In alternative embodiments, the n-type contact layer 203 may comprise any one of InP, InGaAsP, InGaAs or InGaAlAs. The n-type contact layer 203 is n-doped. The n-type contact layer 203 may be heavily doped. In certain embodiments, the n-type contact layer 203 may be n-doped at a concentration from approximately 1.0×10¹⁸ cm⁻³ to approximately 5.0×10¹⁹ cm⁻³. The n-type contact layer 203 may have a thickness from approximately 100 nm to approximately 1000 nm. For the embodiment shown in FIG. 3, thickness of each layer in the device 200 is measured in a direction from the substrate 201 to the p-type contact layer 202. The thicknesses of the layers in FIG. 3 are not shown to scale. In the embodiment shown in FIG. 3, the p-type contact layer 202 may comprise InGaAs. In alternative embodiments, the p-type contact layer 202 may comprise InP, InGaAsP, InAlAs or InGaAlAs. The p-type contact layer 202 is p-doped. The p-type contact layer 202 may be heavily doped. In certain embodiments the p-type contact layer 202 may be p-doped at a concentration from approximately 1.0×10¹⁸ cm⁻³ to approximately 5.0×10¹⁹ cm⁻³. The p-type contact layer 202 may have a thickness from approximately 30 nm to approximately 50 nm. As shown in FIG. 3, one or more electrodes 205 may be provided on each of the n-type contact layer 203 and the p-type contact layer 202. In the embodiment in FIG. 3, one electrode is provided on each of the n-type contact layer 203 and the p-type contact layer 202. The electrode 205 provided on the p-type contact layer 202 is in the shape of a ring. Therefore, the cross-section of the device 200 shown FIG. 3 illustrates two parts of a single ring-shaped electrode 205.

The device 200 comprises an avalanche layer 206 comprising antimony (Sb). The avalanche layer 206 is disposed between the p-type contact layer 202 and the n-type contact layer 203. The avalanche layer 206 may be intrinsic. The avalanche layer 206 may have a thickness of between 75 and 2000 nm. In the embodiment shown in FIG. 3, the avalanche layer 206 may comprise AlGaAsSb. In certain embodiments, the avalanche layer 206 may comprise AlₓGa₁₋ₓAs_{y}Sb_{1-y}, where x is between 0.4 and 1.0 inclusive and optionally between 0.85 and 1.0 inclusive. In certain embodiments, y may be chosen to lattice match the avalanche layer 206 to an InP substrate 201. In certain embodiments, the avalanche layer 206 may comprise AlₓGa₁₋ₓAs_{y}Sb_{1-y}, where x is 0.85 and y is 0.56. In alternative embodiments, the avalanche layer 206 may instead comprise InAlAsSb or AlAsSb.

As shown in FIG. 3, the SAMAPD device 200 has a multi-stage structure. The multi-stage structure comprises a first stage 207 and a second stage 208. The first stage 207 comprises the p-type contact layer 202 and the second stage 208 comprises the avalanche layer 206. As shown in the embodiment in FIG. 3, the first stage 207 may be positioned centrally on the second stage 208. The second stage 208 may be positioned centrally relative to the substrate 201. As shown in the embodiment in FIG. 3, the first stage 207 comprises a sidewall 209 and the second stage 208 comprises a sidewall 210. The sidewall 209 of the first stage may extend in a direction from the second stage 208 towards an upper surface 211 of the device 200. The sidewall 210 of the second stage 208 may extend in a direction from the substrate 201 towards the first stage 207. As shown in FIG. 3, the layers in the first and second stages 207, 208 each extend to the respective sidewall 209, 210 of the stage 207, 208. Whilst the embodiment shown in FIG. 3 comprises two stages, in alternative embodiments the multi-stage structure may comprise two, three or more stages.

The first stage 207 has a smaller cross-sectional area than the second stage 208 where the cross-sectional area is defined as being perpendicular to a direction from the substrate 201 to the p-type contact layer 202. Therefore, the width of the p-type contact layer 202 is smaller than the width of the avalanche layer 206. As shown in FIG. 3, the layers in the first stage 207 have substantially the same cross-sectional area as each other and the layers in the second stage 208 have substantially the same cross-sectional area as each other.

In a similar manner as the embodiment shown in FIG. 1, the multi-stage structure ensures that, during use, the region of the device 200 having a high electric field is confined to the area beneath the p-type contact layer 202 as shown by the area between the dashed lines 240 in FIG. 3. The high electric field region does not extend to the sidewalls of the second stage 208. As such, the multi-stage structure produces a device 200 having improved performance and reliability.

In certain embodiments, the distance between a sidewall 209 of the first stage 207 and a sidewall 210 of the second stage 208 in a direction from the substrate 201 to the n-type contact layer 203 is between 5 μm and 100 μm. At distances of 5 μm or more, the high electric field region is away from the sidewalls of the avalanche layer 206 during use. In certain embodiments, the distance between the sidewall 209 of the first stage 207 and the sidewall 210 of the second stage 208 may be at least 15 μm. At such distances, the high electric field region is sufficiently far from the sidewalls of the avalanche layer 206 that the risk of hotspots forming at the sidewalls of the avalanche layer 206 due to irregularities is significantly reduced and the tolerance of the device 200 to imperfections is further improved compared to distances of less than 15 μm. In certain embodiments the distance between the sidewall of the first stage 207 and the sidewall of the second stage 208 may be 30 μm or less to limit the size and capacitance of the device 200.

In the non-limiting specific embodiment shown in FIG. 3, the multi-stage structure is a multi-stage mesa structure. The first stage 207 is a first mesa and the second stage 208 is a second mesa.

As shown in FIG. 3, the multi-stage structure may be a stepped structure, the first stage 207 providing a first step and the second stage 208 providing a second step. The first set may be relative to the second stage 208. The second step may be relative to the substrate 201. That is, the second step has a smaller cross-sectional area than the substrate 201, where the cross-sectional area is defined as being perpendicular to a direction from the substage to the p-type contact layer 202. As shown in FIG. 3, each step may have sidewalls that are substantially perpendicular to the substrate 201. Each step may have an upper surface 211, 212 that is substantially parallel to the substrate 201.

In certain non-limiting embodiments, each of the layers within the device 200 may have a substantially circular cross-section, where the cross-section is in a direction perpendicular to the direction from the substrate 201 to the p-type contact layer 202. Therefore, each of the first stage 207 and the second stage 208 may be substantially cylindrical in shape. However, the invention is not limited to each layer of the device 200 having a substantially circular cross-section. Each layer may have any suitable cross-section. In certain embodiments, each layer may have a substantially rectangular or square cross-section where each corner of the rectangle or square may be rounded. a multi-stage structure in combination with an avalanche layer 206 comprising antimony in an SAMAPD device 200 produced unexpected synergistic advantages due to low noise characteristics and wide band gap of the avalanche layer 206. The properties of an antimony based avalanche layer 206 enable a greater thickness to be used for the avalanche layer 206 than in other known devices which has beneficial consequences in the multi-stage structure. In certain embodiments, the avalanche layer 206 may have a thickness of between 300 to 1000 nm. A thick avalanche layer 206 may significantly reduce the peak electric field across the avalanche region that is needed for avalanche gain. As such, the effect of any imperfections in the device 200 on its performance is reduced.

The device 200 comprises an APD sub-assembly. The APD sub-assembly may comprise a sub-set of the features of the device 200 shown in FIG. 3. For the embodiment shown in FIG. 3, the APD sub-assembly comprises the substrate 201, the n-type contact layer 203 formed on the substrate 201 and the p-type contact layer 202. The sub-assembly also comprises the avalanche layer 206 comprising antimony that is disposed between the n-type contact layer 203 and the p-type contact layer 202. The APD sub-assembly has the multi-stage structure comprising the first stage 207 comprising the p-type contact layer 202 and the second stage 208 comprising the avalanche layer 206. As described above, the first stage 207 has a smaller cross-sectional area than the second stage 208, the cross-sectional area being perpendicular to a direction from the substrate 201 to the p-type contact layer 202. As such, the APD sub-assembly is a constituent part of the device 200. The device 200 may comprise further features in addition to the APD sub-assembly. The APD sub-assembly may optionally comprise one or more additional features of the device 200 that are shown in and described with reference to FIG. 3.

As shown in the embodiment in FIG. 3, the device 200 may comprise a spacer layer 213. The spacer layer 213 may be included in the APD sub-assembly. The spacer layer 213 may be disposed between the avalanche layer 206 and the p-type contact layer 202. The spacer layer 213 may be intrinsic. The spacer layer 213 may have a thickness between 50 nm and 4000 nm. The spacer layer 213 comprises a lower portion 213a and an upper portion 213b. The upper portion 213b has a smaller cross-sectional area than the lower portion 213a, the cross-sectional area being perpendicular to the direction from the substrate 201 to the p-type contact layer 202. As shown in FIG. 3, the lower portion 213a resides within the second stage 208 and the upper portion 213b resides within the first stage 207. As such, the second stage 208 may comprise the lower portion 213a and the first stage 207 may comprise the upper portion 213b. As shown in FIG. 3, the first stage 207 begins within the spacer layer 213. Therefore, when manufacturing the device 200, the device 200 may advantageously be etched so that the transition between the first and second stages 207, 208 occurs within the spacer layer 213. The transition between the first and second stages 207, 208 may occur at any point within the spacer layer 213. This may improve the ease of manufacturing the device 200.

Additionally, the lower portion 213a of the spacer layer 213 defines an upper boundary of the second stage 208. As shown in FIG. 3, the lower portion 213a of the spacer layer 213 provides an upper surface 212 of the second stage 208 and ensures that the sidewalls of the avalanche layer 206 are the only external surfaces of the avalanche layer 206. As described above, the spacer layer 213 improves the ease of manufacturing the device as the transition between the first and second stages 207, 208 may occur at any point within the spacer layer 213. Additionally, ending the second stage within the spacer layer 213 rather than at the avalanche layer 206 may also enable surface leakage to be reduced.

In certain embodiments, the spacer layer may not comprise antimony. In the embodiment shown in FIG. 3, the spacer layer may comprise InAlAs. In alternative embodiments, the spacer layer 213 may comprise InP. As described above, antimony may oxidise heavily when used as an etch stop during wet etching. Therefore, providing a spacer layer 213 which does not comprise antimony may help to create a uniform electric field across the avalanche layer 206 in the second stage 208 and confines the peak electric field away from the external surfaces of the device 200. As only a low electric field extends across the external surfaces of the avalanche layer 206, the spacer layer 213 may improve the tolerance of the device 200 to irregularities and defects from manufacture.

In certain embodiments, the spacer layer 213 may also reduce the capacitance of the device 200 thereby improving the performance of the device 200. The spacer layer 213 may achieve this by increasing the thickness of the device 200. This may be most beneficial when the device 200 is used in low speed applications such as LIDAR. In certain embodiments, the spacer layer 213 may have a thickness of between 250 nm and 4000 nm to reduce the capacitance of the device 200. However, when the device 200 is used in high speed applications, such as telecommunications, the reduction in capacitance from a thick spacer layer 213 may be less important that the speed of the device 200 is capable. Therefore, in certain embodiments, the spacer layer 213 may have a thickness of between 50 to 250 nm.

The device 200 may comprise one or more additional layers positioned between the spacer layer 213 and the p-type contact layer 202. These layers may be in the first stage 207 of the multi-stage structure as shown in FIG. 3.

The device 200 may comprise an absorption layer 217 disposed between the avalanche layer 206 and the p-type contact layer 202. The APD sub-assembly may comprise the absorption layer 217. In the embodiment in FIG. 3, the absorption layer 217 is disposed between the spacer and the p-type contact layer 202. As such, the first stage of the multi-stage structure may comprise the absorption layer 217. In the embodiment shown in FIG. 3, the absorption layer 217 may comprise InGaAs. In alternative embodiments, the absorption layer 217 may comprise any one of InGaAlAs, InGaAsP, GaAsSb or an InGaAs/GaAsSb type-II superlattice. In certain embodiments, the absorption layer 217 may be intrinsic. The absorption layer 217 may have a thickness from approximately 500 nm to approximately 2500 nm.

The device 200 may comprise a transition portion 218 disposed between the avalanche layer 206 and the absorption layer 217. The APD sub-assembly may comprise the transition portion 218. As shown in FIG. 3, the first stage 207 of the multi-stage structure may comprise the transition portion 218. Therefore, the transition portion is disposed between the spacer layer 213 and the absorption layer 217.

The transition portion 218 may comprise a first grading layer 219 and a charge sheet 220. The charge sheet 220 may be disposed between the first grading layer 219 and the avalanche layer 206. The charge sheet 220 may have a bandgap between the bandgap of the absorption layer 217 and the bandgap of the avalanche layer 206. As shown in FIG. 3, the charge sheet 220 may be formed on the spacer layer 213. The absorption layer 217 may be formed on the first grading layer 219.

The charge sheet 220 in the embodiment in FIG. 3 has substantially the same effect as that described above for the charge sheet 120 of the embodiment in FIG. 1. In certain embodiments, the charge sheet 220 may be p-doped. In certain embodiments, the charge sheet 220 may be p-doped at a concentration between 1×10¹⁷ cm⁻³ and 1×10¹⁸ cm⁻³, and optionally between 1×10¹⁷ cm⁻³ and 5×10¹⁷ cm⁻³. In certain embodiments, the charge sheet 220 may have a thickness between 40 nm and 300 nm. In certain embodiments, the charge sheet 220 may comprise InAlAs. In certain embodiments, the charge sheet 220 may have a bandgap of 1 eV or greater.

In certain embodiments, the first grading layer 219 may have a constant bandgap across its thickness. In the embodiment shown in FIG. 3, the first grading layer 219 may comprise AlGaInAs. In alternative embodiments, the first grading layer 219 may comprise InGaAsP. The first grading layer 219 may be intrinsic. The first grading layer 219 may have a thickness from approximately 25 nm to approximately 50 nm.

As shown in the embodiment in FIG. 3, the transition portion 218 may comprise a second grading layer 221 disposed between the first grading layer 219 and the charge sheet 220. In certain embodiments, the second grading layer 221 may have a constant bandgap across its thickness. In the embodiment shown in FIG. 3, the second grading layer 221 may comprise AlGaInAs. In alternative embodiments, the second grading layer 221 may comprise InGaAsP. The second grading layer 221 may be intrinsic. The second grading layer 221 may have a thickness from approximately 25 nm to approximately 50 nm. The second grading layer 221 has a different bandgap to that of the first grading layer 219. The second grading layer 221 may have a bandgap between the bandgap of the first grading layer 219 and the charge sheet 220.

The device 200 may comprise a third grading layer 230 disposed between the absorption layer 217 and the p-type contact layer 202. The APD sub-assembly may comprise the third grading layer 230. As shown in the embodiment in FIG. 3, the first stage 207 of the multi-stage structure may comprise the third grading layer 230. The third grading layer 230 may be formed on the absorption layer 217. In the embodiment shown in FIG. 3, the third grading layer 230 is on the opposing side of the absorption layer 217 to the transition portion 218. In the embodiment shown in FIG. 3, the third grading layer 230 may comprise AlGaInAs. The third grading layer 230 may be intrinsic. In alternative embodiments, the third grading layer 230 may comprise InGaAsP.

As shown in the embodiment in FIG. 3, the third grading layer 230 may comprise two discrete layers 230a, 230b. Each layer may have a different bandgap. The third grading layer 230 may comprise a first layer 230a formed on the absorption layer 217 and a second layer formed 230b on the first layer 230a. The first layer 230a of the third grading layer 230 may have a bandgap between the bandgap of the absorption layer 217 and the second layer 230b of the third grading layer 230. In the embodiment shown in FIG. 3, each layer in the third grading layer 230 may comprise AlGaInAs. The third grading layer 230 may have a thickness from approximately 50 nm to approximately 100 nm. Each of the first and second layers of the third grading layer 230 may have the same thickness as one another. As such, the first and second layers of the third grading layer 230 may each have a thickness from approximately 25 nm to approximately 50 nm. In alternative embodiments, each layer of the third grading layer 230 may comprise InGaAsP.

The device 200 may comprise a first cladding layer 214. The APD sub-assembly may comprise the first cladding layer 214. As shown in the embodiment in FIG. 3, the first cladding layer 214 may be disposed between the absorption layer 217 and the p-type contact layer 202. The first cladding layer 214 may be formed on the third grading layer 230. The p-type contact layer 202 may be formed on the first cladding layer 214. As shown in FIG. 3, the first stage 207 of the multi-stage structure may comprise the first cladding layer 214. In the embodiment shown in FIG. 3, the first cladding layer 214 may comprise InAlAs. The first cladding layer 214 may have a thickness from approximately 50 nm to approximately 500 nm. In certain embodiments, the first cladding layer 214 may be p-doped. The concentration of the dopant in the first cladding layer 214 may be from approximately 1.0×10¹⁸ cm⁻³ to approximately 1.0×10¹⁹ cm⁻³. The concentration of the dopant in the first cladding layer 214 may be less than the concentration of the dopant in the p-type contact layer 202.

Therefore, as shown in the embodiment of FIG. 3, the device 200 may comprise a charge sheet 220, a second grading layer 221, a first grading layer 219, an absorption layer 217, a third grading layer 230 and a cladding layer 214 positioned between the spacer layer 213 and the p-type contact layer 202 in the first stage 207. However, the invention is not limited to the specific layers or order of layers shown in FIG. 3.

The device 200 may comprise one or more additional layers positioned between the n-type contact layer 203 and the spacer layer 213. These layers may be in the first stage 207 of the multi-stage structure as shown in FIG. 3.

The device 200 may comprise a field control layer 216. The APD sub-assembly may comprise the field control layer 216. As shown in FIG. 3, second stage 208 of the multi-stage structure may comprise the field control layer 216. The field control layer 216 may be disposed between the avalanche layer 206 and the spacer layer 213. The field control layer 216 may be formed on the avalanche layer 206. The spacer layer 213 may be formed on the field control layer 216. As such, the field control layer 216 may be disposed on the opposing side of the spacer layer 213 than the charge sheet 220.

The field control layer 216 may be p-doped. The concentration of the dopant in the field control layer 216 may be from approximately 1.0×10¹⁷ cm⁻³ to approximately 1.0×10¹⁸ cm⁻³. In certain embodiments, the field control layer 216 may not comprise antimony. Therefore, in a similar manner to the spacer layer 213, the field control layer 216 may further help reduce the risk of oxidization to the avalanche layer 206 during manufacture using wet or dry etching. In the embodiment shown in FIG. 3, the field control layer 216 may comprise InAlAs. In alternative embodiments, the field control layer 216 may comprise InGaAlAs, InP or InGaAsP. The field control layer 216 may have a thickness of approximately 70 nm. In certain embodiments, the field control layer 216 may comprise substantially the same material as the charge sheet 220. In certain embodiments, the field control layer 216 may be substantially the same as the charge sheet 220.

The device 200 may comprise a second cladding layer 231. The APD sub-assembly may comprise the second cladding layer 231. As shown in the embodiment of FIG. 3, the second cladding layer 231 may be disposed between the avalanche layer 206 and the n-type contact layer 203. The second cladding layer 231 may be formed on the n-type contact layer 203. The avalanche layer 206 may be formed on the second cladding layer 231. As shown in FIG. 3, the second stage 208 of the multi-stage structure may comprise the second cladding layer 231.

In the embodiment shown in FIG. 3, the second cladding layer 231 may comprise InAlAs. The second cladding layer 231 may have a thickness from approximately 200 nm to approximately 750 nm. In certain embodiments, the second cladding layer 231 may be n-doped. The concentration of the dopant in the second cladding layer 231 may be from approximately 1.0×10¹⁸ cm⁻³ to approximately 1.0×10¹⁹ cm⁻³.

Therefore, as shown in the embodiment of FIG. 3, the device 200 may comprise a cladding layer 231, an avalanche layer 206 and a field control layer 216 positioned between the n-type contact layer 203 and the spacer layer 213 in the second stage 208. However, the invention is not limited to the specific layers or order of layers shown in FIG. 3.

As described above, the second cladding layer 231 may be formed on the n-type contact. In the embodiment shown in FIG. 3, the n-type contact layer 203 is formed on the substrate 201. As shown in the embodiment in FIG. 3, the n-type contact layer 203 may have a greater cross-sectional area than the second stage 208 the substrate 201, where the cross-sectional area is perpendicular to a direction from the substrate 201 to the p-type contact layer 202. Thus, the second stage 208 of the device 200 may not comprise the n-type contact layer 203. Rather, the second stage 208 of the device 200 may be formed on the n-type contact layer 203. In certain embodiments, the n-type contact may have substantially the same cross-sectional area as the substrate 201, where the cross-sectional area is perpendicular to a direction from the substrate 201 to the p-type contact layer 202. As such, the one or more electrodes 205 may be formed on the n-type contact layer 203.

However, the invention is not limited to the positioning of the n-type contact layer 203 shown in FIG. 3. In alternative embodiments, the second stage 208 of the multi-stage structure may comprise at least part of the n-type contact layer 203. In certain embodiments, the n-type contact layer 203 may reside within the second stage 208. That is, the second stage 208 may comprise substantially the entirety of the n-type contact layer 203. In certain embodiments, the n-type contact layer 203 may comprise an upper portion and a lower portion. The second cladding layer 231 may be formed on the upper portion of the n-type contact layer 203. The lower portion of the n-type contact layer 203 may be adjacent to the substrate 201. The second stage 208 of the multi-stage structure may comprise the upper portion of the n-type contact layer 203. The upper portion of the n-type contact layer 203 may have a smaller cross-sectional area than both the lower portion of the n-type contact layer 203 and the substrate 201, where the cross-sectional area is defined as being perpendicular to a direction from the substrate 201 to the n-type contact layer 203. As such, the lower portion of the n-type contact layer 203 may not reside with the second stage 208 of the device 200. The second stage 208 may therefore begin within the n-type contact layer 203. The lower portion of the n-type contact layer 203 may have substantially the same cross-sectional area as the substrate 201. One or more electrodes 205 may be formed on the lower portion of the n-type contact layer 203.

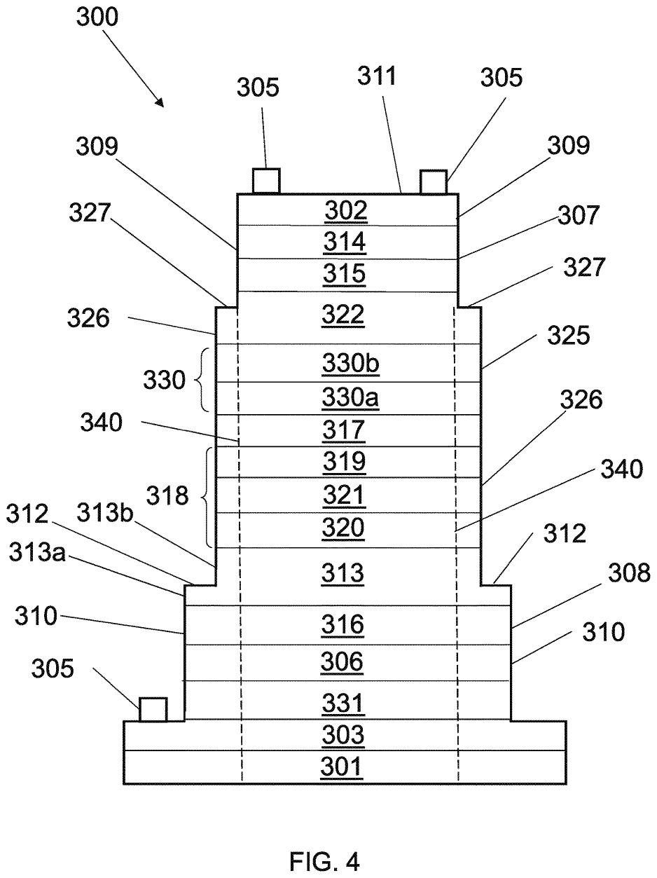

In another embodiment, shown in FIG. 4, there is provided an SAMAPD device 300. The SAMAPD device 300 comprises a substrate 301 and an n-type contact layer 303 formed on the substrate 301. The SAMAPD device 300 also comprises a p-type contact layer 302. As shown in FIG. 4, the device 300 is in a p-i-n configuration as the n-type contact layer 303 is grown on the substrate 301. As such, the p-type contact layer 302 may form an external layer of the device 300. Therefore, the device 300 of the embodiment shown in FIG. 4 has an alternative p-i-n configuration compared to the device 200 of the embodiment shown in FIG. 3. In the embodiment shown in FIG. 4, the substrate 301 may comprise InP. In certain embodiments, any semiconductor materials within the device 300 (i.e. disposed on the substrate 301) may be lattice matched to InP. In the embodiment shown in FIG. 4, the n-type contact layer 303 may comprise InAlAs. In alternative embodiments, the n-type contact layer 303 may comprise any one of InP, InGaAsP, InGaAs or InGaAlAs. The n-type contact layer 303 is n-doped. The n-type contact layer 303 may be heavily doped. In certain embodiments, the n-type contact layer 303 may be n-doped at a concentration from approximately 1.0×10¹⁸ cm⁻³ to approximately 5.0×10¹⁹ cm⁻³. The n-type contact layer 303 may have a thickness from approximately 100 nm to approximately 1000 nm. For the embodiment shown in FIG. 4, the thickness of each layer in the device 300 is measured in a direction from the substrate 301 to the p-type contact layer 302. The thicknesses of the layers in FIG. 4 are not shown to scale. In the embodiment shown in FIG. 4, the p-type contact layer 302 may comprise InGaAs. In alternative embodiments, the p-type contact layer 302 may comprise InP, InGaAsP, InAlAs or InGaAlAs. The p-type contact layer 302 is p-doped. The p-type contact layer 302 may be heavily doped. In certain embodiments the p-type contact layer 302 may be p-doped at a concentration from approximately 1.0×10¹⁸ cm⁻³ to approximately 5.0×10¹⁹ cm⁻³. The p-type contact layer 302 may have a thickness from approximately 30 nm to 100 nm. As shown in FIG. 4, one or more electrodes 305 may be provided on each of the n-type contact layer 303 and the p-type contact layer 302. In the embodiment in FIG. 4, one electrode is provided on each of the n-type contact layer 303 and the p-type contact layer 302. The electrode 305 provided on the p-type contact layer 302 is in the shape of a ring. Therefore, the cross-section of the device 300 shown FIG. 4 illustrates two parts of a single ring-shaped electrode 305.

The device 300 comprises an avalanche layer 306 comprising antimony (Sb). The avalanche layer 306 is disposed between the p-type contact layer 302 and the n-type contact layer 303. The avalanche layer 306 may be intrinsic. The avalanche layer 306 may have a thickness of between 75 and 3000 nm. In the embodiment shown in FIG. 4, the avalanche layer 306 may comprise AlGaAsSb. In certain embodiments, the avalanche layer 306 may comprise AlₓGa₁₋ₓAs_{y}Sb_{1-y}, where x is between 0.4 and 1.0 inclusive and optionally between 0.85 and 1.0 inclusive. In certain embodiments, y may be chosen to lattice match the avalanche layer 306 to an InP substrate 301. In certain embodiments, the avalanche layer 306 may comprise AlₓGa₁₋ₓAs_{y}Sb_{1-y}, where x is 0.85 and y is 0.56. In alternative embodiments, the avalanche layer 306 may instead comprise InAlAsSb or AlAsSb.

As shown in FIG. 4, the SAMAPD device 300 has a multi-stage structure. The multi-stage structure comprises a first stage 307 and a second stage 308. The first stage 307 comprises the p-type contact layer 302 and the second stage 308 comprises the avalanche layer 306. The device 300 also comprises a third stage 325 disposed between the second stage 308 and the first stage 307. As shown in the embodiment in FIG. 4, the first stage 307 may be positioned centrally on the third stage 325. The third stage 325 may be positioned centrally on the second stage 308. The second stage 308 may be positioned centrally relative to the substrate 301. As shown in the embodiment in FIG. 4, the first stage 307 comprises a sidewall 309, the second stage 308 comprises a sidewall 310 and the third stage 325 comprises a sidewall 326. The sidewall 309 of the first stage may extend in a direction from the third stage 325 towards an upper surface 311 of the device 300. The sidewall 310 of the second stage 308 may extend in a direction from the substrate 301 towards the first stage 307. The sidewall 326 of the third stage 325 may extend in a direction from the second stage 308 to the first stage 307. As shown in FIG. 4, the layers in the first, second and third stages 307, 308, 325 each extend to the respective sidewall 309, 310, 326 of the stage 307, 308, 325. Whilst the embodiment shown in FIG. 4 comprises three stages, in alternative embodiments the multi-stage structure may comprise three, four or more stages.

The first stage 307 has a smaller cross-sectional area than both the third stage 325 and the second stage 308 where the cross-sectional area is defined as being perpendicular to a direction from the substrate 301 to the p-type contact layer 302. Therefore, the width of the p-type contact layer 302 is smaller than the width of the avalanche layer 306.

The third stage 325 has a smaller cross-sectional area than the second stage 308 where the cross-sectional area is defined as being perpendicular to a direction from the substrate 301 to the p-type contact layer 302. As shown in FIG. 4, the layers in the first stage 307 have substantially the same cross-sectional area as each other, the layers in the second stage 308 have substantially the same cross-sectional area as each other and the layers in the third stage 325 have substantially the same cross-sectional area as each other.

In a similar manner as the embodiment shown in FIG. 1, the multi-stage structure ensures that, during use, the region of the device 300 having a high electric field is confined to the area beneath the p-type contact layer 302 as shown by the area between the dashed lines in FIG. 4. The high electric field region does not extend to the sidewalls of the second stage 308. As such, the multi-stage structure produces a device 300 having improved performance and reliability.

In certain embodiments, the distance between a sidewall 309 of the first stage 307 and a sidewall 310 of the second stage 308 in a direction perpendicular to the direction from the substrate 301 to the n-type contact layer 303 is between 5 μm and 100 μm. At distances of 5 μm or more, the high electric field region is away from the sidewalls of the avalanche layer 306 during use. In certain embodiments, the distance between the sidewall 309 of the first stage 307 and the sidewall 310 of the second stage 308 may be at least 15 μm. At such distances, the high electric field region sufficiently far from the sidewalls of the avalanche layer 306 that the risk of hotspots forming at the sidewalls of the avalanche layer 306 due to irregularities is significantly reduced and the tolerance of the device 300 to imperfections is further improved compared to distances of less than 15 μm. In certain embodiments the distance between the sidewall of the first stage 307 and the sidewall of the second stage 308 may be 30 μm or less to limit the size and capacitance of the device 300.

In the non-limiting specific embodiment shown in FIG. 4, the multi-stage structure is a multi-stage mesa structure. The first stage 307 is a first mesa, the second stage 308 is a second mesa and the third stage 325 is a third mesa. Thus, the device 300 is a triple mesa structure. The devices 100, 200 shown in FIGS. 1 and 2 are double mesa structures.

As shown in FIG. 4, the multi-stage structure may be a stepped structure. The first stage 307 providing a first step, the second stage 308 providing a second step and the third stage 325 providing a third step. The first step may be relative to the third stage 325. The third step may be relative to the second stage 308. The second step may be relative to the substrate 301. That is, the second step has a smaller cross-sectional area than the substrate 301, where the cross-sectional area is defined as being perpendicular to a direction from the substrate to the p-type contact layer 302. As shown in FIG. 4, each step may have sidewalls that are substantially perpendicular to the substrate 301. Each step may have an upper surface 311, 312, 327 that is substantially parallel to the substrate 301.

In certain non-limiting embodiments, each of the layers within the device 300 may have a substantially circular cross-section, where the cross-section is in a direction perpendicular to the direction from the substrate 301 to the p-type contact layer 302. Therefore, each of the first stage 307, the second stage 308 and the third stage 325 may be substantially cylindrical in shape. However, the invention is not limited to each layer of the device 300 having a substantially circular cross-section. Each layer may have any suitable cross-section. In certain embodiments, each layer may have a substantially rectangular or square cross-section where each corner of the rectangle or square may be rounded.

In a similar manner as the embodiment shown in FIG. 1, the inventors found that using a multi-stage structure in combination with an avalanche layer 306 comprising antimony in an SAMAPD device 300 produced unexpected synergistic advantages due to low noise characteristics and wide band gap of the avalanche layer 306. The properties of an antimony based avalanche layer 306 enable a greater thickness to be used for the avalanche layer 306 than in other known devices which has beneficial consequences in the multi-stage structure. In certain embodiments, the avalanche layer 306 may have a thickness of between 300 to 1000 nm. A thick avalanche layer 306 may significantly reduce the peak electric field across the avalanche region that is needed for avalanche gain. As such, the effect of any imperfections in the device 300 on its performance is reduced.

As described above for the device 200 of the embodiment shown in FIG. 3, the device 300 comprises an APD sub-assembly. The APD sub-assembly may comprise a sub-set of the features of the device 300 shown in FIG. 4. For the embodiment shown in FIG. 4, the APD sub-assembly comprises the substrate 301, the n-type contact layer 303 formed on the substrate 301 and the p-type contact layer 302. The sub-assembly also comprises the avalanche layer 306 comprising antimony that is disposed between the n-type contact layer 303 and the p-type contact layer 302. The APD sub-assembly has the multi-stage structure comprising the first stage 307 comprising the p-type contact layer 302 and the second stage 308 comprising the avalanche layer 306. As described above, the first stage 307 has a smaller cross-sectional area than the second stage 308, the cross-sectional area being perpendicular to a direction from the substrate 301 to the p-type contact layer 302. As such, the APD sub-assembly is a constituent part of the device 300. The device 300 may comprise further features in addition to the APD sub-assembly. The APD sub-assembly may optionally comprise one or more additional features of the device 300 that are shown in and described with reference to FIG. 4.

As shown in the embodiment in FIG. 4, the device 300 may comprise a first spacer layer 313. The spacer layer 313 may be included in the APD sub-assembly. The spacer layer 313 may be disposed between the avalanche layer 306 and the p-type contact layer 302. The first spacer layer 313 may be intrinsic. The first spacer layer 313 may have a thickness between 50 nm and 4000 nm. The first spacer layer 313 comprises a lower portion 313a and an upper portion 313b. The upper portion 313b has a smaller cross-sectional area than the lower portion 313a, the cross-sectional area being perpendicular to the direction from the substrate 301 to the p-type contact layer 302. As shown in FIG. 4, the lower portion 313a resides within the second stage 308 and the upper portion 313b resides within the third stage 325. As such, the second stage 308 comprises the lower portion 313a and the third stage 325 comprises the upper portion 313b. As shown in FIG. 4, the third stage 325 begins within the first spacer layer 313. Therefore, when manufacturing the device 300, the device 300 may advantageously be etched so that the transition between the second and third stages 308, 325 occurs within the first spacer layer 313. The transition between the second and third stages 308, 325 may occur at any point within the first spacer layer 313. This may improve the ease of manufacturing the device 300.

Additionally, the lower portion 313a of the first spacer layer 313 defines an upper boundary of the second stage 308. As shown in FIG. 4, the lower portion 313a of the first spacer layer 313 provides an upper surface 312 of the second stage 308 and ensures that the sidewalls of the avalanche layer 306 are the only external surfaces of the avalanche layer 306. As described above, the first spacer layer 313 improve the ease of manufacturing the device as the transition between the second and third stages 308, 325 may occur at any point within the first spacer layer 313. Additionally, ending the second stage within the first spacer layer 313 rather than at the avalanche layer 306 may also enable surface leakage to be reduced.

In certain embodiments, the spacer layer may not comprise antimony. In the embodiment shown in FIG. 4, the spacer layer may comprise InAlAs. In alternative embodiments, the first spacer layer 313 may comprise InP. As described above, antimony may oxidise heavily when used as an etch stop during wet etching. Therefore, providing a first spacer layer 313 which does not comprise antimony may help to create a uniform electric field across the avalanche layer 306 in the second stage 308 and confines the peak electric field away from the external surfaces of the device 300. As only a low electric field extends across the external surfaces of the avalanche layer 306, the first spacer layer 313 may improve the tolerance of the device 300 to irregularities and defects from manufacture.

In certain embodiments, the first spacer layer 313 may also reduce the capacitance of the device 300 thereby improving the performance of the device 300. The first spacer layer 313 may achieve this by increasing the thickness of the device 300. This may be most beneficial when the device 300 is used in low speed applications such as LIDAR. In certain embodiments, the first spacer layer 313 may have a thickness of between 250 nm and 4000 nm to reduce the capacitance of the device 300. However, when the device 300 is used in high speed applications, such as telecommunications, the reduction in capacitance from a thick first spacer layer 313 may be less important that the speed of the device 300 is capable. Therefore, in certain embodiments, the first spacer layer 313 may have a thickness of between 50 to 300 nm.

As shown in the embodiment in FIG. 4, the device 300 may comprise a second spacer layer 322 disposed between the first spacer layer 313 and the p-type contact layer 302. The APD sub-assembly may comprise second spacer layer 322. The second spacer layer 322 may be intrinsic. The second spacer layer 322 may have a thickness between 50 nm and 4000 nm. The second spacer layer 322 comprises a lower portion 322a and an upper portion 322b. The upper portion 322b has a smaller cross-sectional area than the lower portion 322a, the cross-sectional area being perpendicular to the direction from the substrate 301 to the p-type contact layer 302. As shown in FIG. 4, the lower portion 322a resides within the third 325 and the upper portion 322b resides within the first stage 307. As such, the third stage 325 comprises the lower portion 322a and the first stage 307 comprises the upper portion 322b. As shown in FIG. 4, the first stage 307 begins within the second spacer layer 322. Therefore, when manufacturing the device 300, the device 300 may advantageously be etched so that the transition between the first and third stages 307, 325 occurs within the second spacer layer 322. The transition between the first and third stages 307, 325 may occur at any point within the second spacer layer 322. This may improve the ease of manufacturing the device 300.

In certain embodiments, the spacer layer may not comprise antimony. In the embodiment shown in FIG. 4, the spacer layer may comprise InAlAs. In alternative embodiments, the second spacer layer 322 may comprise InP. As described above, antimony may oxidise heavily when used as an etch stop during wet etching. Therefore, providing a second spacer layer 322 that defines an upper surface 327 of the third stage 325 and which does not comprise antimony may improve the performance of the device 300.

In certain embodiments, the second spacer layer 322 may also reduce the capacitance of the device 300 thereby improving the performance of the device 300. The second spacer layer 322 may achieve this by increasing the thickness of the device 300. In certain embodiments, the second spacer layer 322 may have a thickness of between 250 nm and 4000 nm to reduce the capacitance of the device 300. However, when the device 300 is used in high speed applications, such as telecommunications, the reduction in capacitance from a thick second spacer layer 322 may be less important that the speed of the device 300 is capable. Therefore, in certain embodiments, the second spacer layer 322 may have a thickness of between 50 to 300 nm.

As shown in FIG. 4, the device 300 may comprise one or more additional layers positioned between the second spacer layer 323 and the p-type contact layer 302. These layers may be in the first stage 307 of the multi-stage structure as shown in FIG. 4.

The device 300 may comprise a first cladding layer 314. The APD sub-assembly may comprise the first cladding layer 314. As shown in the embodiment in FIG. 4, the first cladding layer 314 may be disposed between the second spacer layer 322 and the p-type contact layer 302. The first cladding layer 314 may be formed on the second spacer layer 322. The p-type contact layer 302 may be formed on the first cladding layer 314. As shown in FIG. 4, the first stage 307 of the multi-stage structure may comprise the first cladding layer 314. In the embodiment shown in FIG. 4, the first cladding layer 314 may comprise InAlAs. The first cladding layer 314 may have a thickness from approximately 50 nm to approximately 500 nm. In certain embodiments, the first cladding layer 314 may be p-doped. The concentration of the dopant in the first cladding layer 314 may be from approximately 1.0×10¹⁸ cm⁻³ to approximately 1.0×10¹⁹ cm⁻³. The concentration of the dopant in the first cladding layer 314 may be less than the concentration of the dopant in the p-type contact layer 302.

The device 300 may comprise a graded cladding layer 315 between the second spacer layer 322 and the p-type contact layer 302. The APD sub-assembly may comprise graded cladding layer 315. The graded cladding layer 315 may be formed on the upper portion 322b of the second spacer layer 322. The graded cladding layer 315 may therefore be disposed between the second spacer layer 313 and the first cladding layer 314. As such, the first stage 307 may comprise the graded cladding layer 315. The graded cladding layer 315 may be p-doped. The concentration or level of the dopant within the graded cladding layer 315 may increase in a direction from the substrate 301 the p-type contact layer 303. In certain embodiments, the concentration of the dopant may increase from 1.0×10¹⁶ cm⁻³ to 1.0×10¹⁸ cm⁻³. In certain embodiments, the concentration of the dopant may increase to or towards that of the first cladding layer 314. In the embodiment shown in FIG. 4, the graded cladding layer 315 may comprise InAlAs. In alternative embodiments, the graded cladding layer 315 may comprise InP, InGaAlAs or InGaAsP. The graded cladding layer 315 may have a thickness from approximately 100 nm to approximately 500 nm.

In certain embodiments, the doping of the graded cladding layer 315 may be graded so that the concentration of the dopant is substantially the same as that in one or both of the adjacent layers in the device 300 at the interface between the layers. The graded cladding layer 315 may be substantially intrinsic adjacent to the interface between the second spacer layer 322 and the graded cladding layer 315. The concentration of the dopant in the graded cladding layer 315 may be substantially the same as that in the first cladding layer 314 adjacent to the interface between the graded cladding layer 315 and the first cladding layer 314. Grading the graded cladding layer 315 in this way may help to further reduce the occurrence of hotspots in the device 300 during use by reducing abrupt changes in grading.

Therefore, as shown in the embodiment of FIG. 4, the device 300 may comprise a graded cladding layer 315 and a first cladding layer 314 positioned between the second spacer layer 322 and the p-type contact layer 302 in the first stage 307. However, the invention is not limited to the specific layers or order of layers shown in FIG. 4.

The device 300 may comprise one or more additional layers positioned between the n-type contact layer 303 and the first spacer layer 313. These layers may be in the second stage 308 of the multi-stage structure as shown in FIG. 4.

The device 300 may comprise a field control layer 316. The APD sub-assembly may comprise the field control layer 316. As shown in FIG. 4, the second stage 308 of the multi-stage structure may comprise the field control layer 316. The field control layer 316 may be disposed between the avalanche layer 306 and the first spacer layer 313. The field control layer 316 may be formed on the avalanche layer 306. The first spacer layer 313 may be formed on the field control layer 316.

The field control layer 316 may be p-doped. The concentration of the dopant in the field control layer 316 may be from approximately 1.0×10¹⁷ cm⁻³ to approximately 1.0×10¹⁸ cm⁻³. In certain embodiments, the field control layer 316 may not comprise antimony. Therefore, in a similar manner to the first spacer layer 313, the field control layer 316 may further help reduce the risk of oxidization to the avalanche layer 306 during manufacture using wet etching. In the embodiment shown in FIG. 4, the field control layer 316 may comprise InAlAs. In alternative embodiments, the field control layer 316 may comprise InGaAlAs, InP or InGaAsP. The field control layer 316 may have thickness from approximately 30 nm to approximately 250 nm.

The device 300 may comprise a second cladding layer 331. The APD sub-assembly may comprise the second cladding layer 331. As shown in the embodiment of FIG. 4, the second cladding layer 331 may be disposed between the avalanche layer 306 and the n-type contact layer 303. The second cladding layer 331 may be formed on the n-type contact layer 303. The avalanche layer 306 may be formed on the second cladding layer 331. As shown in FIG. 4, the second stage 308 of the multi-stage structure may comprise the second cladding layer 331.

In the embodiment shown in FIG. 4, the second cladding layer 331 may comprise InAlAs. The second cladding layer 331 may have a thickness from approximately 100 nm to approximately 750 nm. In certain embodiments, the second cladding layer 331 may be n-doped. The concentration of the dopant in the second cladding layer 331 may be from approximately 1.0×10¹⁸ cm⁻³ to approximately 1.0×10¹⁹ cm⁻³.

Therefore, as shown in the embodiment of FIG. 4, the device 300 may comprise a second cladding layer 331, an avalanche layer 306 and a field control layer 316 positioned between the n-type contact layer 303 and the first spacer layer in the second stage 308. However, the invention is not limited to the specific layers or order of layers shown in FIG. 4.

The device 300 may comprise one or more additional layers positioned between the first spacer layer 313 and the second spacer layer 322. These layers may be in the third stage 325 of the multi-stage structure as shown in FIG. 4.

The device 300 may comprise an absorption layer 317 disposed between the avalanche layer 306 and the p-type contact layer 302. The APD sub-assembly may comprise the absorption layer 317. In the embodiment in FIG. 4, the absorption layer 317 is disposed between the first spacer layer 313 and the second spacer layer 322. As such, the third stage 325 of the multi-stage structure may comprise the absorption layer 317. In the embodiment shown in FIG. 4, the absorption layer 317 may comprise InGaAs. In alternative embodiments, the absorption layer 317 may comprise any one of InGaAlAs, GaAsSb, InGaAsP, or an InGaAs/GaAsSb type-II superlattice. In certain embodiments, the absorption layer 317 may be intrinsic. The absorption layer 317 may have a thickness from approximately 500 nm to approximately 2500 nm.

The device 300 may comprise a transition portion 318 disposed between the avalanche layer 306 and the absorption layer 317. The APD sub-assembly may comprise the transition portion 318. As shown in FIG. 4, the third stage 325 of the multi-stage structure may comprise the transition portion 318. Therefore, the transition portion 318 may be disposed the first and second spacer layers 313, 322. As shown in FIG. 4, the transition portion 318 may be disposed between the first spacer layer 313 and the absorption layer 317.

The transition portion 318 may comprise a first grading layer 319 and a charge sheet 320. The charge sheet 320 may be disposed between the first grading layer 319 and the avalanche layer 306. The charge sheet 320 may have a bandgap between the bandgap of the absorption layer 317 and the bandgap of the avalanche layer 306. As shown in FIG. 4, the charge sheet 320 may be formed on the first spacer layer 313. As such, the charge sheet 320 may be disposed on the opposing side of the first spacer layer 313 than the field control layer 316. The absorption layer 317 may be formed on the first grading layer 319.

The charge sheet 320 in the embodiment in FIG. 4 has substantially the same effect as that described above for the charge sheet 120 of the embodiment in FIG. 1. In certain embodiments, the charge sheet 320 may be p-doped. In certain embodiments, the charge sheet 320 may be p-doped at a concentration between 1×10¹⁷ cm⁻³ and 1×10¹⁸ cm⁻³, and optionally between 1×10¹⁷ cm⁻³ and 5×10¹⁷ cm⁻³. In certain embodiments, the charge sheet 320 may have a thickness between 40 nm and 300 nm. In certain embodiments, the charge sheet 320 may comprise InAlAs. In certain embodiments, the charge sheet 320 may have a bandgap of 1 eV or greater. In certain embodiments, the charge sheet 320 may comprise substantially the same material as the field control layer 316. In certain embodiments, the charge sheet 320 may be substantially the same as field control layer 316.

In certain embodiments, the first grading layer 319 may have a constant bandgap across its thickness. In the embodiment shown in FIG. 4, the first grading layer 319 may comprise AlGaInAs. In alternative embodiments, the first grading layer 319 may comprise InGaAsP. The first grading layer 319 may be intrinsic. The first grading layer 319 may have a thickness from approximately 25 nm to approximately 50 nm

As shown in the embodiment of FIG. 4, the transition portion 318 may comprise a second grading layer 321 disposed between the first grading layer 319 and the charge sheet 320. In certain embodiments, the second grading layer 321 may have a constant bandgap across its thickness. In the embodiment shown in FIG. 4, the second grading layer 321 may comprise AlGaInAs. In alternative embodiments, the second grading layer 321 may comprise InGaAsP. The second grading layer 321 may be intrinsic. The second grading layer 321 may have a thickness from approximately 25 nm to approximately 50 nm. The second grading layer 321 has a different bandgap to the first grading layer 319. The second grading layer 321 may have a bandgap between the bandgap of the first grading layer 319 and the avalanche layer 306.

The device 300 may comprise a third grading layer 330 disposed between the absorption layer 317 and the second spacer layer 322. The APD sub-assembly may comprise third grading layer 330. As shown in the embodiment of FIG. 4, the third stage 325 of the multi-stage structure may comprise the third grading layer 330. The third grading layer 330 may be formed on the absorption layer 317. In the embodiment shown in FIG. 4, the third grading layer 330 is on the opposing side of the absorption layer 317 to the transition portion 318. In the embodiment shown in FIG. 4, the third grading layer 330 comprises AlGaInAs. The third grading layer 330 may be intrinsic.

As shown in the embodiment in FIG. 4, the third grading layer 330 may comprise two discrete layers 330a, 330b, each layer having a different bandgap. The third grading layer 330 may comprise a first layer 330a formed on the absorption layer 317 and a second layer formed 330b on the first layer 330a. The second spacer layer 322 may be formed on the second layer 330b of the third grading layer 330. The first layer 330a of the third grading layer 330 may have a bandgap between the bandgap of the absorption layer 317 and the second layer 330b of the third grading layer 330. In the embodiment shown in FIG. 4, each layer in the third grading layer 330 may comprise AlGaInAs. The third grading layer 330 may have a thickness from approximately 50 nm to 100 nm. Each of the first and second layers of the third grading layer 330 may have the same thickness as one another. As such, the first and second layers of the third grading layer 330 may each have a thickness from approximately 25 nm to approximately 50 nm. In alternative embodiments, each layer of the third grading layer 330 may comprise InGaAsP.

Therefore, as shown in the embodiment of FIG. 4, the device 300 may comprise a charge sheet 320, a second grading layer 321, a first grading layer 319, an absorption layer 317 and a third grading layer 330 positioned between the first spacer layer 313 and the second spacer layer 322 in the third stage 325. However, the invention is not limited to the specific layers or order of layers shown in FIG. 4.

As described above, the second cladding layer 331 may be formed on the n-type contact. In the embodiment shown in FIG. 4, the n-type contact layer 303 is formed on the substrate 301. As shown in the embodiment in FIG. 4, the n-type contact layer 303 may have a greater cross-sectional area than the second stage 308, where the cross-sectional area is perpendicular to a direction from the substrate 301 to the p-type contact layer 302. Thus, the second stage 308 of the device 300 may not comprise the n-type contact layer 303. Rather, the second stage 308 of the device 300 may be formed on the n-type contact layer 303. In certain embodiments, the n-type contact may have substantially the same cross-sectional area as the substrate 301, where the cross-sectional area is perpendicular to a direction from the substrate 301 to the p-type contact layer 302. As such, the one of more electrodes may be formed on the n-type contact layer 303.

However, the invention is not limited to the positioning of the n-type contact layer 303 shown in FIG. 4. In alternative embodiments, the second stage 308 of the multi-stage structure may comprise at least part of the n-type contact layer 303. In certain embodiments, the n-type contact layer 303 may reside within the second stage 308. That is, the second stage 308 may comprise substantially the entirety of the n-type contact layer 303. In certain embodiments, the n-type contact layer 303 may comprise an upper portion and a lower portion. The second cladding layer 331 may be formed on the upper portion of the n-type contact layer 303. The lower portion of the n-type contact layer 303 may be adjacent to the substrate 301. The second stage 308 of the multi-stage structure may comprise the upper portion of the n-type contact layer 303. The upper portion of the n-type contact layer 303 may have a smaller cross-sectional area than both the lower portion of the n-type contact layer 303 and the substrate 301, where the cross-sectional area is defined as being perpendicular to a direction from the substrate 301 to the n-type contact layer 303. As such, the lower portion of the n-type contact layer 303 may not reside with the second stage 308 of the device 300. The second stage 308 may therefore begin within the n-type contact layer 303. The lower portion of the n-type contact layer 303 may have substantially the same cross-sectional area as the substrate 301. One or more electrodes 305 may be formed on the lower portion of the n-type contact layer 303.

The device 300 in the embodiment shown in FIG. 4 with its first, second and third stage structure may have a longer device lifetime and improved reliability than the device 200 in the embodiment shown in FIG. 3. This is because the electric field at the sidewall of both the avalanche layer and absorber layer are lower for the device 300 of the embodiment shown in FIG. 4 than the device 200 of the embodiment shown in FIG. 3. However, the device 400 of the embodiment shown in FIG. 4 may be more complex to manufacture compared to the device 200 of the embodiment shown in FIG. 3.

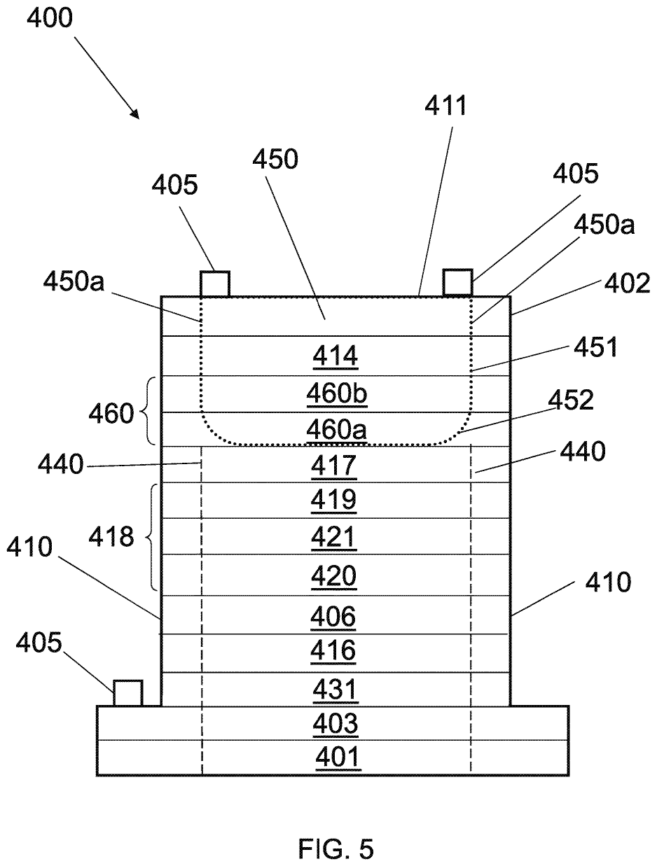

In another embodiment, shown in FIG. 5, there is provided an SAMAPD device 400. The SAMAPD device 400 comprises a substrate 401 and a first contact layer 403 formed on the substrate 401. The SAMAPD device 400 also comprises a second contact layer 402. One or more electrodes 405 may be provided on each of the first contact layer 403 and the second contact layer 402. In the embodiment in FIG. 5, one electrode is provided on each of the first contact layer 403 and the second contact layer 402. The electrode 405 provided on the second contact 402 is in the shape of a ring. Therefore, the cross-section of the device 500 shown FIG. 5 illustrates two parts of a single ring-shaped electrode 405.

The first contact layer 403 is an n-type contact layer. As such, the first contact layer 403 is n-doped. In certain embodiments, the first contact layer 403 may be n-doped at a concentration from approximately 1.0×10¹⁸ cm⁻³ to approximately 2.0×10¹⁹ cm⁻³. The first contact layer 403 may have a thickness from approximately 100 nm to approximately 1000 nm. For the embodiment shown in FIG. 5, the thickness of each layer in the device 400 is measured in a direction from the substrate 401 to the second contact layer 402. The thicknesses of the layers in FIG. 5 are not shown to scale.

The second contact layer 402 comprises a p-type contact region 450 formed by diffusing zinc. The p-type contact region 450 is shown in FIG. 5 by the area of the second contact layer 402 that is between the dotted lines 451. The p-type contact region 450 may be characterized by having a high concentration of zinc atoms. As shown in the embodiment in FIG. 1, the p-type contact region 450 may be a localized region in the second contact layer 402. That is, the p-type contact region 450 may have a smaller width that the second contact layer 402 where the width is in perpendicular to a direction from the substrate 401 to the second contact layer 403. The second contact layer 402 may have a thickness from approximately 25 nm to approximately 50 nm. As shown in FIG. 5, one or more electrodes 405 may be formed on the second contact layer 402. The electrodes 405 may be in contact with the p-type contact region 450.

As shown in FIG. 5, the device 400 is in a p-i-n configuration as the first contact layer 403 is grown on the substrate 401. As such, the second contact layer 402 may form an external layer 411 of the device 400. In the embodiment shown in FIG. 5, the substrate 401 may comprise InP. In certain embodiments, any semiconductor materials within the device 400 (i.e. disposed on the substrate 401) may be lattice matched to InP. In the embodiment shown in FIG. 5, the first contact layer 403 may comprise InAlAs. In alternative embodiments, the first contact layer 403 may comprise any one of InP, InGaAs, GaAsSb InGaAsPor InGaAlAs. In the embodiment shown in FIG. 5, the second contact layer 402 may comprise InGaAs. In alternative embodiments, the second contact layer 402 may comprise InP, InGaAsP, InAlAs or InGaAlAs. As shown in FIG. 5, one or more electrodes 405 may be provided on each of the first contact layer 403 and the second contact layer 402.

The device 400 comprises an avalanche layer 406 comprising antimony (Sb). The avalanche layer 406 is disposed between the second contact layer 402 and the first contact layer 403. The avalanche layer 406 may be intrinsic. The avalanche layer 406 may have a thickness of between 75 and 4000 nm. In the embodiment shown in FIG. 5, the avalanche layer 406 may comprise AlGaAsSb. In certain embodiments, the avalanche layer 406 may comprise AlₓGa₁₋ₓAs_{y}Sb_{1-y}, where x is between 0.4 and 1.0 inclusive and optionally between 0.85 and 1.0 inclusive. In certain embodiments, y may be chosen to lattice match the avalanche layer 406 to an InP substrate 401. In certain embodiments, the avalanche layer 406 may comprise AlₓGa₁₋ₓAs_{y}Sb_{1-y}, where x is 0.85 and y is 0.56. In alternative embodiments, the avalanche layer 406 may instead comprise InAlAsSb or AlAsSb.

As shown in FIG. 5, the p-type contact region 450 has a smaller cross-sectional area than the avalanche layer 406, the cross-sectional area being perpendicular to a direction from the substrate 401 to the second contact layer 402.

The relative sizes of the p-type contact region 450 and the avalanche layer 406 ensures that, during use, the region of the device 400 having a high electric field is substantially confined to the area beneath the p-type contact region 450 as shown by the area between the dashed lines in FIG. 5. The high electric field region does not extend to the sidewalls 410 of the avalanche layer 406. As such, the device 400 has an improved performance and reliability.

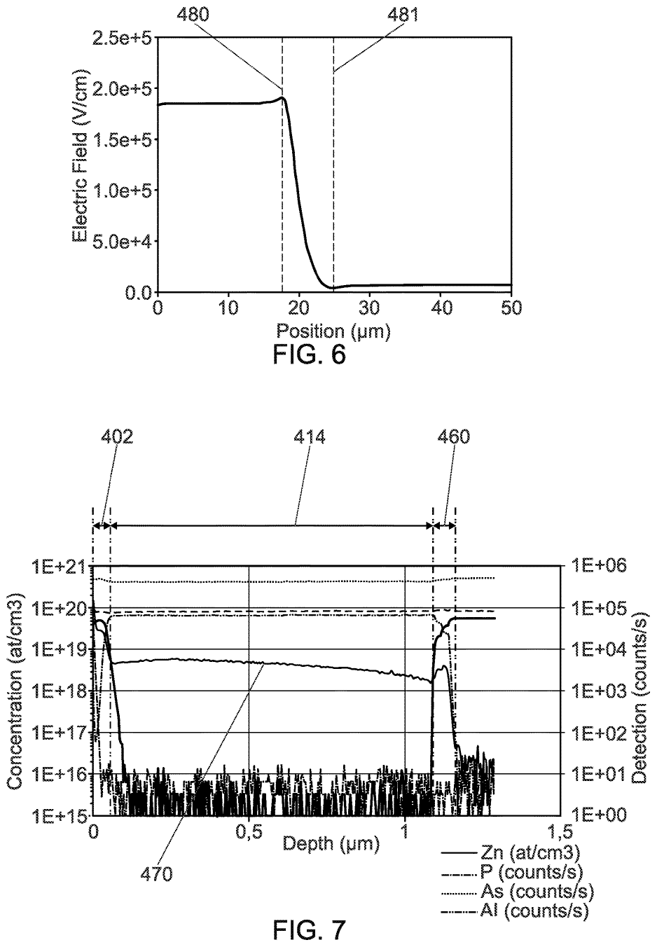

In certain embodiments, the distance between an edge 450a of the p-type contact region 450 and the sidewall 410 of the avalanche layer 406 in a direction from the substrate 401 to the second contact layer 403 may be at least 7.5 μm. At such distances, the high electric field region may be sufficiently far from the sidewalls of the avalanche layer 406 such that the risk of hotspots forming at the sidewalls of the avalanche layer 406 due to irregularities is significantly reduced and the tolerance of the device 400 to imperfections is improved. This is shown in FIG. 6. FIG. 6 shows an example of the electric field in the avalanche layer 406 as a function of the distance from the middle of the avalanche layer 406. In FIG. 6, the center of the avalanche layer 406 is at x=0 μm in FIG. 6 and the sidewall 410 of the avalanche layer is at x=50 μm. In FIG. 6, the position of the edge 450a of the p-type contact region 450 is shown by the first dashed line 480. At distances greater than the position of the first dashed line 480 the electric field rapidly decreases. The electric field reaches its minimum or stable value at the position of the second dashed line 481. The second dashed line 481 is separated from the first dashed line 480 by a distance of 7.5 μm. As such, providing a distance of at least 7.5 μm between the edge 450a of the p-type contact region 450 and the sidewall 410 of the avalanche layer 406 in a direction from the substrate 401 to the second contact layer 403 ensures a significant reduction in the electric field at the sidewall 410 of the avalanche layer 406 thereby providing optimal performance of the device 400. However, at distances of less than 7.5 μm from the edge 450a of the p-type contact region 450 the electric field in the avalanche layer 406 is still reduced. Therefore, whilst optional performance of the device 400 may be achieved with distances of at least 7.5 μm, an improvement of the device 400 performance may still be achieved at distances of less than of 7.5 μm. In certain embodiments the distance between the wall 450a of the p-type contact region 450 and the sidewall 410 of the avalanche layer 406 may be 30 μm or less to limit the size and capacitance of the device.

In the non-limiting specific embodiment shown in FIG. 5, the device is a quasi-planar device. As shown in FIG. 5, the second contact layer 402 may have substantially the same cross-sectional area than the avalanche layer 406, the cross-sectional area being perpendicular to a direction from the substrate 401 to the second contact layer 402. The p-type contact region 450 may be positioned centrally above the avalanche layer 406. As shown in FIG. 5, each of the layers between the second contact-layer 402 and the first contact layer 403 may have substantially the same cross-sectional area as each other, the cross-sectional area being perpendicular to a direction from the substrate 401 to the second contact layer 402.

In certain non-limiting embodiments, each of the layers within the device 400 may have a substantially circular cross-section, where the cross-section is in a direction perpendicular to the direction from the substrate 401 to the second contact layer 402. Therefore, each layer in the device 400 may be substantially cylindrical in shape. However, the invention is not limited to each layer of the device 400 having a substantially circular cross-section. Each layer may have any suitable cross-section. In certain embodiments, each layer may have a substantially rectangular or square cross-section where each corner of the rectangle or square may be rounded.

In certain embodiments, the avalanche layer 406 may have a thickness of 300 nm to 1000 nm. As described above, a thick antimony avalanche layer may make the device 400 less sensitive to voltage during use. A thick avalanche layer 406 may significantly reduce the peak electric field across the avalanche region that is needed for avalanche gain. As such, the effect of any imperfections in the device 400 on its performance is reduced.

The device 400 in the embodiment shown in FIG. 5 comprises an APD sub-assembly. The APD sub-assembly may comprise a sub-set of the features of the device 400 shown in FIG. 5. For the embodiment shown in FIG. 5, the APD sub-assembly comprises the substrate 401, the first contact layer 403 formed on the substrate 401 and the second contact layer 402. The sub-assembly also comprises the avalanche layer 406 comprising antimony that is disposed between the first contact layer 303 and the second contact layer 302. As described above, the first contact layer 403 is an n-type contact layer and the second contact layer 502 comprises a p-type contact region 450 formed by diffusing zinc. The p-type contact region 450 has a smaller cross-sectional area than the avalanche layer 406, the cross-sectional area being perpendicular to a direction from the substrate 401 to the second contact layer 402. As such, the APD sub-assembly is a constituent part of the device 400. The device 400 may comprise further features in addition to the APD sub-assembly. The APD sub-assembly may optionally comprise one or more additional features of the device 400 that are shown in and described with reference to FIG. 5.

The device 400 may comprise one or more additional layers positioned between the avalanche layer 406 and the second contact layer 402.

The device 400 may comprise an absorption layer 417 disposed between the avalanche layer 406 and the second contact layer 402. The APD sub-assembly may comprise the absorption layer 417. In the embodiment shown in FIG. 5, the absorption layer 417 may comprise InGaAs. In alternative embodiments, the absorption layer 417 may comprise any one of InGaAlAs, GaAsSb, InGaAsP, or an InGaAs/GaAsSb type-II superlattice. In certain embodiments, the absorption layer 417 may be intrinsic. The absorption layer 417 may have a thickness from approximately 500 nm to approximately 2500 nm.

The device 400 may comprise a transition portion 418 disposed between the avalanche layer 406 and the absorption layer 417. The APD sub-assembly may comprise the transition portion 118. The transition portion 418 may comprise a first grading layer 419 and a charge sheet 420. The charge sheet 420 may be disposed between the first grading layer 419 and the avalanche layer 406. The charge sheet 420 may have a bandgap between the bandgap of the absorption layer 417 and the bandgap of the avalanche layer 406. As shown in FIG. 5, the charge sheet 420 may be formed on avalanche layer 406. The absorption layer 417 may be formed on the first grading layer 419.

The charge sheet 420 in the embodiment in FIG. 5 has substantially the same effect as that described above for the charge sheet 220 of the embodiment in FIG. 3 In certain embodiments, the charge sheet 420 may be p-doped. In certain embodiments, the charge sheet 420 may be p-doped at a concentration between 1×10¹⁷ cm⁻³ and 1×10¹⁸ cm⁻³, and optionally between 1×10¹⁷ cm⁻³ and 5×10¹⁷ cm⁻³ . In certain embodiments, the charge sheet 420 may have a thickness between 40 nm and 300 nm. In certain embodiments, the charge sheet 420 may comprise InAlAs. In certain embodiments, the charge sheet 420 may have a bandgap of 1 eV or greater.

In certain embodiments, the first grading layer 419 may have a constant bandgap across its thickness. In the embodiment shown in FIG. 5, the first grading layer 419 may comprise AlGaInAs. In alternative embodiments, the first grading layer 419 may comprise InGaAsP. The first grading layer 419 may be intrinsic. The first grading layer 419 may have a thickness from approximately 25 nm to approximately 50 nm.

As shown in the embodiment in Figure, the transition portion 418 may comprise a second grading layer 421 disposed between the first grading layer 419 and the charge sheet 420. In certain embodiments, the second grading layer 421 may have a constant bandgap across its thickness. In the embodiment shown in FIG. 5, the second grading layer 421 may comprise AlGaInAs. In alternative embodiments, the second grading layer 421 may comprise InGaAsP. The second grading layer 421 may be intrinsic. The second grading layer 421 may have a thickness from approximately 25 nm to approximately 50 nm. The second grading layer 421 has a different bandgap to that of the first grading layer 419. The second grading layer 421 may have a bandgap between the bandgap of the first grading layer 419 and the avalanche layer 406.

The device 400 may comprise at least one stopper layer 460 disposed between the absorption layer 417 and the second contact layer 402. The APD sub-assembly may comprise the at least one stopper layer 460. The at least one stopper layer 460 may be on the opposing side of the absorption layer 417 to the transition portion 418. As shown in the embodiment of FIG. 5, the device may comprise a first stopper layer 460a and a second stopper layer 460b. The first stopper layer 460a may be formed on the absorption layer 417. The second stopper layer 460a may be formed on the first stopper layer 460a.

Each stopper layer 460a, 460b has a lower diffusivity of zinc than the second contact layer. As such, the stopper layers 460a, 460b help prevent unwanted diffusion of zinc into the absorption layer 417 during manufacture. In the embodiments shown in FIG. 6, each of the stopper 460a, 460b may comprise InGaAlAs. In alternative embodiments, each of the stopper 460a, 460b may comprise InGaAs or InGaAsP. Each of the stopper layers 460a, 460b may be intrinsic. Each of the stopper layers 460a, 460b may have the same thickness as one another. The first and second stopper layers 460a, 460b may each have a thickness from approximately 25 nm to approximately 100 nm.

The first and second stopper layers 460a, 460b may also provide a similar function to that of the first and second layers 230a, 230b of the third grading layer 230 of the embodiment shown in FIG. 3. As such, each stopper layer 460a, 460b may have a different bandgap. The first stopper layer 460a may have a bandgap between the bandgap of the absorption layer 417 and the second stopper layer 460b.

The device 400 may comprise a first cladding layer 414. The APD sub-assembly may comprise the first cladding layer 414. As shown in the embodiment in FIG. 5, the first cladding layer 414 may be disposed between the absorption layer 417 and the second contact layer 402. The first cladding layer 414 may be formed on the second stopper layer 460b. The second contact layer 402 may be formed on the first cladding layer 414. In the embodiment shown in FIG. 5, the first cladding layer 414 may comprise InAlAs. In alternative embodiments, the first cladding layer 414 may comprise InP. In certain embodiments, the first cladding layer 414 may be intrinsic.

As shown in FIG. 5, the device 400 comprises a zinc diffusion area 451 shown by the area inside the dotted line in the Figure. The zinc diffusion area 451 defines an area in the device 400 where zinc has significantly diffused into the layers during manufacture. The zinc diffusion area 451 therefore comprises the p-type contact region 450. As shown in FIG. 5, the zinc diffusion area 451 extends into the first cladding layer 414 and may extend into one stopper layer 460. In certain embodiments, the first cladding layer 414 may have a thickness from approximately 500 nm to approximately 5000 nm. The first cladding layer 414 may be thicker than is typical of known SAMAPDs. The thick cladding layer results in a longer zinc diffusion process to manufacture the device 400. As such, the corners 452 of the zinc diffusion area 451 are rounded which reduces the likelihood of electric field hotspots forming during use. As described above, the at least one stopper layer 460 may limit the diffusion of zinc into the absorption layer 417. In certain embodiments, the first cladding layer 414 may have a thickness of approximately 1000 nm or more.

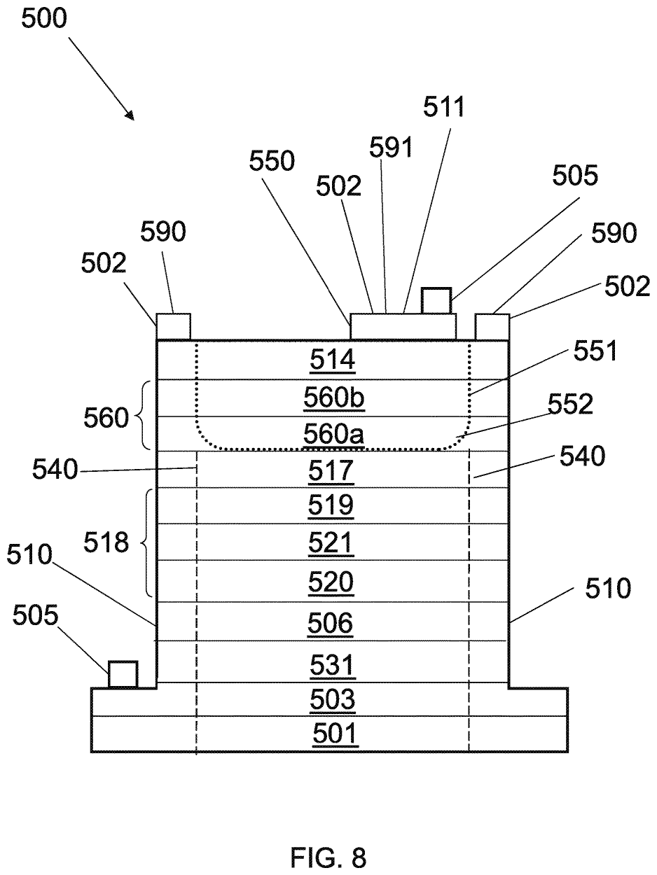

FIG. 7 shows an example of the concentration of zinc across the zinc diffusion area 451 for an embodiment of the device 400. FIG. 7 shows the concentration of zinc atoms per cm³ in the p-type contact region 450 of the second contact layer 402, first cladding layer 414 and at least one stopper layer 460. In the embodiment of FIG. 7, the second contact layer has a thickness of 50 nm, the first cladding layer has a thickness of 1000 nm and the at least one stopper layer has a thickness of 50 nm. As shown in FIG. 7, the concentration of zinc atoms is highest in the second contact layer 402 where the p-type contact region 450 is formed. The concentration of zinc atoms in the second contact layer 402 is between 4×10¹⁸ cm⁻³ and 2×10²⁰ cm⁻³. The concertation of zinc atoms decreases in the first cladding layer 414. The concentration of zinc atoms in the first cladding layer 414 is between 1.4×10¹⁸ cm⁻³ and 4.0×10¹⁸ cm⁻³. As shown in FIG. 7, the concentration of zinc atoms in the stopper layer 460 at the interface between the stopper layer and the absorption layer is significantly lower than the concentration of zinc atoms in the stopper layer 460 at the interface between the stopper layer and the first cladding layer 414. The concentration of zinc atoms in the stopper layer 460 at the interface between the stopper layer 460 and the absorption layer 417 is approximately 4.0×10¹⁶ cm⁻³ and the concentration of zinc atoms in the stopper layer 460 at the interface between the stopper layer 460 and the first cladding layer 414 is approximately 1.4×10¹⁸ cm⁻³. As such, FIG. 7 shows that the at least one stopper layer 460 is effective at helping to prevent unwanted diffusion of zinc into the absorption layer 417 during manufacture.

As shown in FIG. 5, the zinc diffusion area 451 has a substantially uniform thickness. That is, except for the rounded corners 452 the thickness of the zinc diffusion area 451 is uniform. In the embodiment shown in FIG. 5, the zinc diffusion area 451 has a substantially uniform width, where the width is in a direction perpendicular to the direction from the substrate 401 to the second contact layer 402. That is, except for the rounded corners 452 the width of the zinc diffusion area 451 is uniform. This uniform profile is a result of the device 400 being manufactured by a single zinc diffusion step. As such, the zinc diffusion area 452 does not have a stepped profile within the device 400 between the second contact layer 402 and the absorption layer 417.

As shown in FIG. 5, the width of the p-type contact region 450 is substantially the same as the width of the zinc diffusion area in the first cladding layer 414 and the at least one stopper layer 460.

In certain embodiments, the distance between the edge 450a of the p-type contact region 450 and the sidewall 410 of the avalanche layer 406 in a direction from the substrate 401 to the second contact layer 402 is substantially the same distance between an edge of the zinc diffusion area and the sidewall 410 of the avalanche layer 406 in a direction from the substrate 401 to the second contact layer 402. The edge of the zinc diffusion area is shown by the dotted line in FIG. 5. Therefore, in the same manner as described above for the p-type contact region 450 and the avalanche layer 406, the distance between the edge of the zinc diffusion area 451 and the sidewall 410 of the avalanche layer 406 in a direction from the substrate 401 to the second contact layer 402 may be at least 7.5 μm. The performance of the device 400 may be optimal when the distance between the edge of the zinc diffusion area and the sidewall 410 of the avalanche layer 406 is 7.5 μm or greater. At such distances, the high electric field region may be sufficiently far from the sidewalls of the avalanche layer 406 such that the risk of hotspots forming at the sidewalls of the avalanche layer 406 due to irregularities is significantly reduced and the tolerance of the device 400 to imperfections is improved. In certain embodiments, the distance between the edge of the zinc diffusion area 451 and the sidewall 410 of the avalanche layer 406 may be 30 μm or less to limit the size and capacitance of the device.

Therefore, as shown in the embodiment of FIG. 5, the device 400 may comprise a charge sheet 420, a second grading layer 421, a first grading layer 419, an absorption layer 417, at least one stopper layer 460 and a first cladding layer 414 positioned between the avalanche layer 406 and the second contact layer 402. However, the invention is not limited to the specific layers or order of layers shown in FIG. 5.

The device 400 may comprise one or more additional layers positioned between the first contact layer 403 and the avalanche layer 406.

The device 400 may comprise a second cladding layer 431. The APD sub-assembly may comprise the second cladding layer 431. As shown in the embodiment in FIG. 5, the second cladding layer 431 may be disposed between the first contact layer 403 and the avalanche layer 406. The second cladding layer 431 may be formed on the first contact layer 403.

In the embodiment shown in FIG. 5, the second cladding layer 431 may comprise InAlAs. In alternative embodiments, the second cladding layer 431 may comprise InP, InGaAlAs, InGaAsP, AlGaAsSb, AlAsSb or InAlAsSb. The second cladding layer 431 may have a thickness from approximately 30 nm to approximately 250 nm. In certain embodiments, the second cladding layer 431 may be n-doped. The concentration of the dopant in the second cladding layer 431 may be from approximately 1.0×10¹⁷ cm⁻³ to approximately 1.0×10¹⁸ cm⁻³. The concentration of the dopant in the second cladding layer 431 may be less than the concentration of the dopant in the first contact layer 403.

The device 400 may comprise a field control layer 416. The APD sub-assembly may comprise the field control layer 416. The field control layer 416 may be disposed between the first contact layer 403 and the avalanche layer 406. As shown in the embodiment in FIG. 5, the field control layer 416 may be formed on the second cladding layer 431. The avalanche layer 406 may be formed on the field control layer 431. As such, the field control layer 416 may be disposed on the opposing side of the avalanche layer 406 to the transition portion 418.

The field control layer 416 may be n-doped. The concentration of the dopant in the field control layer 416 may be 1.0×10¹⁷ cm⁻³ to approximately 1.0×10¹⁹ cm⁻³. In certain embodiments, the field control layer 416 may comprise antimony. In the embodiment of FIG. 5, the field control layer 416 may comprise AlGaAsSb. In certain embodiments, the field control layer 416 may comprise AlₓGa₁₋ₓAs_{y}Sb_{1-y}, where x is between 0.4 and 1.0 inclusive and optionally between 0.85 and 1.0 inclusive. In certain embodiments, y may be chosen to lattice match the field control layer 416 to an InP substrate 401. In certain embodiments, the field control layer 416 may comprise AlₓGa₁₋ₓAs_{y}Sb_{1-y}, where x is 0.85 and y is 0.56. In certain embodiments, the field control layer 416 and the avalanche layer may each comprise AlₓGa₁₋ₓAs_{y}Sb_{1-y}, where x and y are the same for both layers. In alternative embodiments, the field control layer 416 may comprise InAlAsSb or AlAsSb. In certain embodiments, the field control layer 416 may have thickness from approximately 50 nm to approximately 200 nm.

Therefore, as shown in the embodiment of FIG. 5, the device 400 may comprise a second cladding layer 431, and a field control layer 416 positioned between the first contact layer 403 and the avalanche layer 406. However, the invention is not limited to the specific layers or order of layers shown in FIG. 5.

As described above, the second cladding layer 431 may be formed on first contact layer 403. In the embodiment shown in FIG. 5, the first contact layer 403 is formed on the substrate 401. As shown in the embodiment in FIG. 5, the first contact layer 403 may have a greater cross-sectional area than the second cladding layer 431 and all subsequent layers layered on the first contact layer 403, where the cross-sectional area is perpendicular to a direction from the substrate 401 to the second contact layer 402. In the embodiment shown in FIG. 5, the second cladding layer 431, the field control layer 416, the charge sheet 420, the second grading layer 421, the first grading layer 419, the absorption layer 417, the at least one stopper layer 460, the cladding layer 414 and the second contact layer 403 all have the same cross-section area, where the cross-sectional area is perpendicular to a direction from the substrate 401 to the second contact layer 402. One or more electrodes 405 may be formed on the first contact layer 403 as shown in FIG. 5.

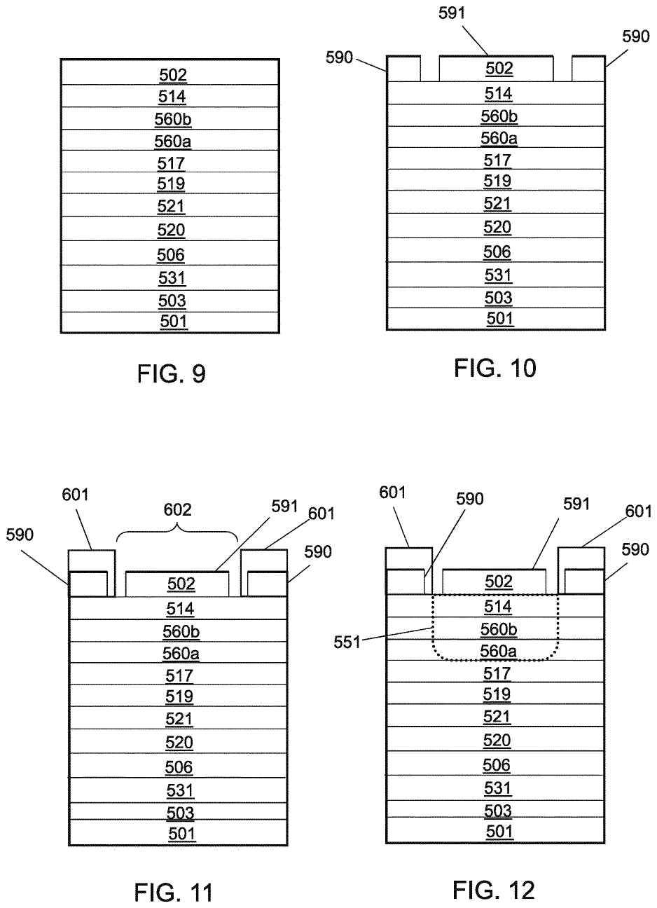

In another embodiment, shown in FIG. 8, there is provided an SAMAPD device 500. The SAMAPD device 500 in FIG. 8 and its APD sub-assembly are the same as the SAMAPD device 400 of FIG. 5 with the exception of the configuration of the second contact layer 502, the configuration of the p-type contact region 550. Reference numerals in FIG. 8 correspond to those used in FIG. 5 for the same features but are transposed by 100.

In the embodiment of FIG. 5, the second contact layer 402 is continuous and has the same width as the adjacent first cladding layer 414. The second contact layer 402 has substantially the same cross-sectional area than the avalanche layer 406, the cross-sectional area being perpendicular to a direction from the substrate 401 to the second contact layer 402. The p-type contact region 450 comprises a localized region of the second contact layer 402. That is, the p-type contact region 450 extends across a part of, but not the entirety of, the second contact layer 402. However, in the embodiment in FIG. 8, the second contact layer 502 has an alternative configuration.

As shown in the embodiment in FIG. 8, the second contact layer 502 may not be continuous. Whilst the p-type contact region 550 comprises a localized region of the second contact layer 502 in the embodiment in FIG. 8, the portion of the second contact layer 502 comprising the p-type contact region 550 is separated from the remainder of the second contact layer 502.

The second contact layer 502 may comprise an outer first portion 590 which extends about a periphery of the device 500. As described above, the each of the layers within the device 500 may have a substantially circular cross-section, where the cross-section is in a direction perpendicular to the direction from the substrate 501 to the second contact layer 502. As such, the first portion 590 of the second contact layer 502 may be in the shape of a ring. However, the invention is not limited to each layer of the device 500 having a substantially circular cross-section. Each layer may have any suitable cross-section. In certain embodiments, each layer may have a substantially rectangular or square cross-section where each corner of the rectangle or square may be rounded.

The second contact layer 502 comprises an inner second portion 591. As shown in FIG. 8, the second portion 502 is the p-type contact region 550. The second portion 591 may be separated from the first portion 590 of the second contact layer 502. During manufacture, the first and second portions 590, 591 may be separated from one another by etching. The second portion 591 of the second contact layer 502 may not be central in the device 500. However, the distance between a sidewall of the second portion 591 (i.e. the p-type contact region 550) and the sidewall 510 of the avalanche layer 506 in a direction perpendicular to the direction from the substrate 501 to the second contact layer 503 may be at least 7.5 μm. As shown in FIG. 8, an electrode 505 may be formed on the second portion 591 of the second contact layer 502.

In the embodiment shown in FIG. 8, the cross-sectional area of the zinc diffusion area 551 may be greater than the cross-sectional area of the p-type contact region 550, where the cross-sectional area is defined as being perpendicular to a direction from the substrate 501 to the second contact layer 502.

The SAMAPD device 500 shown in FIG. 8 may be manufactured using the following method in accordance with an embodiment of the invention.

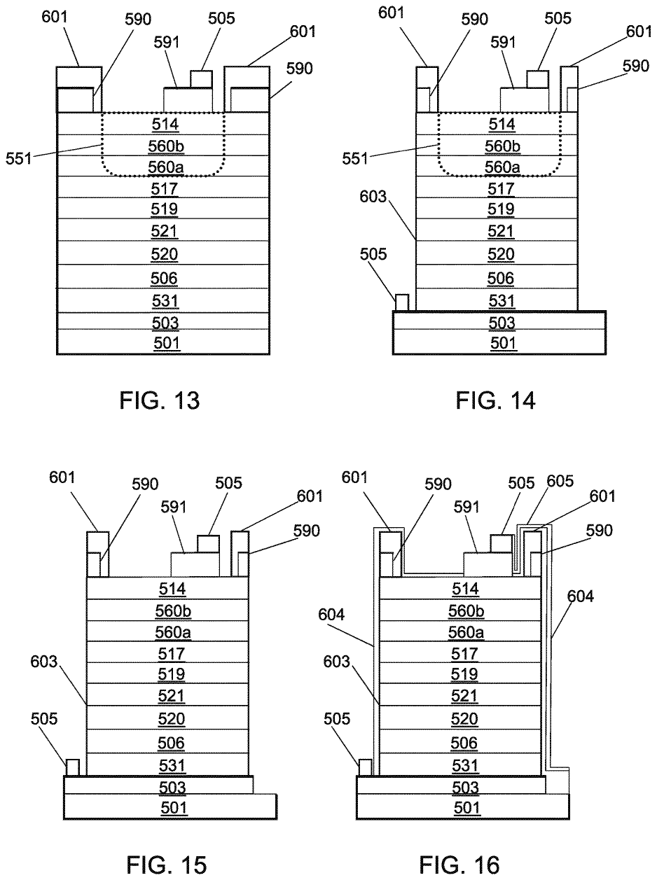

The method comprises providing the substrate 501 and forming the first contact layer 503 on the substrate 501. The method comprises layering a plurality of layers on the substrate. The plurality of layers comprise the avalanche layer 506 and the second contact layer 502. The plurality of layers may also comprise one or more of the second cladding layer 531, the charge sheet 520, the second grading layer 521, the first grading layer 519, the absorption layer 517, the at least one stopper layer 560 and the first cladding layer 514 as shown in FIG. 9. The plurality of layers are arranged on the substrate such that the avalanche layer 506 is disposed between the first and second contact layers 503, 502.

The method may comprise etching the second contact layer 502 to separate the second contact layer 502 into the first portion 590 and the second portion 591. The etching may expose a part of the first cladding layer 514 as shown in FIG. 10. As such, the second contact layer 502 may no longer be continuous. This etching may be done to help define the boundary of the zinc diffusion area 550 that will be formed in the device 500. The second contact layer 502 may be etched so that in the final device 500 the distance between the edge of the zinc diffusion area 550 and the sidewall 510 of the avalanche layer 506 in a direction perpendicular to the direction from the substrate 501 to the second contact layer 503 in the device 500 may be at least 7.5 μm. In embodiments where the second contact layer 502 may comprise InGaAs, the second contact layer may be etched using citric acid.

The method may then comprise applying first mask 601 over the second contact layer 502 and exposed part of the first cladding layer 514. The first mask 601 may be dry etched to expose a window 602 for zinc diffusion as shown in FIG. 11. As such, zinc may diffuse into the plurality of layers in the area beneath the window. The window 602 may have a width of between 15 μm and 500 μm where the width is a direction perpendicular to the direction from the substrate 501 to the second contact layer 502. The window 602 may begin at a location between the first and second portions 590, 591 of the second contact layer 502. As such, the first portion 590 of the second contact layer 502 may be covered by the first mask 601 after the dry etching has been completed. Therefore, the first mask 601 may inhibit zinc diffusion into the first portion 590 of the second contact layer 502. In certain embodiments, the first mask may comprise silicon nitride. The first mask 601 may be applied by plasma deposition.

The method may then comprise creating a p-type contact region 550 in the second contact layer by diffusing zinc into the second contact layer 502. Zinc may be diffused, until the concentration of zinc atoms in the second portion 591 of the second contact layer 502 is at least 4.0×10¹⁸ cm⁻³. When creating the p-type contact region 550 the zinc may also diffuse into the first cladding layer 514 and one stopper layer 560. The stopper layer may substantially prevent zinc diffusing into the absorption 517 layer. FIG. 12 shows the resulting zinc diffusion area 551 of the diffusion step. The zinc diffusion area 551 includes the second portion 591 of the second contact layer 502 and extends into the first cladding layer 514 and the at least one stopper layer 560. The zinc diffusion area 551 is formed under the window 602. In order to create the p-type contact region 550, the method may comprise only a single zinc diffusion step. That is, the p-type contact region 550 may be created by diffusing zinc only once into the second contact layer 502.

After the step of zinc diffusion, an electrode 505 may be formed on the second portion 591 of the second contact layer 502 as shown in FIG. 13. The electrode may be formed by deposition.

The method may comprise etching the second portion 590 of the second contact layer 502 to further reduce the size of the second portion 590, as shown in FIG. 13, thereby providing the final shape of p-type contact region 550. In certain embodiments, the second portion 590 of the second contact layer 502 may be etched using citric acid. As shown in FIG. 8, the final shape of the p-type contact layer 500 may therefore have a smaller cross-sectional area than the avalanche layer 506, where the cross-sectional area is defined as being perpendicular to a direction from the substrate 501 to the second contact layer 503. This may reduce attenuation of light entering the device thereby improving the amount of light absorbed by the absorption layer.

The method may comprise etching the plurality of layers. The plurality of layers may be etched from the first mask 601 on the second contact layer 502 to the interface between the first contact layer 503 and the second cladding layer 531. As such, the device is provided with a sidewall 603 extending from the interface between the first contact layer 503 and the second cladding layer 531 to the top of the device 500. A portion of the sidewall 603 of the device 500 defines the sidewall 510 of the avalanche layer 506. The plurality of layers may be etched so that a distance between the sidewall 510 of the avalanche layer 506 and the p-type contact region 550 in a direction perpendicular to a direction from the substrate 501 to the second contact layer 502 may be at least 7.5 μm. The plurality of layers may be etched so that the distance between the sidewall 510 of the avalanche layer 506 and the edge of the p-type contact region is 30 μm or less. The plurality of layers may be etched so that the distance between the edge of the zinc diffusion area 550 in the first cladding layer 514, and optionally the at least one stopper layer 560, and the sidewall 610 of the avalanche layer 506 in a direction perpendicular to the direction from the substrate 501 to the second contact layer 503 in the device 500 is at least 7.5 μm. The plurality of layers may be etched so that the distance between the edge of the zinc diffusion area 550 in the first cladding layer 514, and optionally the at least one stopper layer 560, and the sidewall 610 of the avalanche layer 506 is 30 μm or less.

Etching of the plurality of layers exposes a portion of the first contact layer 503. Therefore, once the etching of the plurality of layers has been completed, an electrode 505 may be formed on the exposed portion of the first contact layer 503 as shown in FIG. 14. The electrode may be formed by deposition.

In certain embodiments, the method may further comprise etching the first contact layer 503 to expose the substrate on which the first contact layer is formed as shown in FIG. 15. The first contact layer 503 may be etched using an acid etch.

The method may comprise depositing a second mask 604 over the device 500. As such, second mask 604 may cover the first mask 601, the exposed part of the first cladding layer 514, the p-type contact region 550, the electrodes 505, over the sidewall 603 of the device, the exposed part of the first contact layer 503 and the exposed part of the substrate 501. The device 500 may then be etched to remove part of the second mask 604 to expose the electrodes 505 and the p-type contact region 550 as shown in FIG. 16. In certain embodiments, the second mask 604 may comprise silicon nitride. A remote bond pad 605 may be deposited on the device. The remote bond pad 605 may extend from the electrode 505 on the p-type contact region 550 along the sidewall 603 of the device 550 and end in a location above the portion of the substrate 501 from which the first contact layer 503 was etched away as shown in FIG. 16. The remote bond pad 605 may comprise the same material as the electrodes 505. The remote bond pad 605 may improve the ease of providing electrical connections to the device. As such, in certain embodiments, the device 500 of may comprise one or more silicon nitrate deposits 601, 604 and a remote bond pad 605.

The above-described method may be adapted to provide the device shown in FIG. 5. For example, when providing the device of FIG. 5, the step of etching the second contact layer to provide separate first and second portions of the second contact layer and the step of etching the second portion of the second contact layer to reduce the size of the second portion may not be performed. As such, the device 400 may comprise a continuous second contact layer 402. The method may still comprise applying the mask 601 to the periphery of the second contact layer and etching the mask 601 to expose a window 602 for zinc diffusion.

It will be appreciated that various changes and modifications can be made to the present invention without departing from the scope of the present application.

In the specific non-limiting embodiment shown in FIG. 1, the first stage 107 comprises the n-type contact layer 103, the first cladding layer 114, the graded cladding layer 115 and the upper portion 113b of the spacer layer 113, and the second stage 108 comprises the lower portion 113a of the spacer layer 113, the field control layer 116, the avalanche layer 106, the transition portion 118, the absorption layer 117, the third grading layer 122 and the upper portion 102b of the p-type contact layer 102. However, the invention is not limited to the two stages or arrangement of layers in each stage of the embodiment in FIG. 1. In alternative embodiments, the multi-stage structure may comprise two, three or more stages. In such embodiments, each stage may have a different cross-section area, where the cross-sectional area is defined as being perpendicular to a direction from the substrate 101 to the n-type contact layer 103. The cross-sectional area of each stage may decrease in a direction from the substrate 101 to the n-type contact layer 103. The layers in the device 100 may be distributed across the three or more stages in any suitable manner provided the n-type contact layer 103 is in a different stage to the avalanche layer 106 and the stage comprising the n-type contact layer 103 has a smaller cross-sectional area than the stage comprising the avalanche layer 106. Additionally, the device or APD sub-assembly is not limited to the specific layers or order of layers described in relation to the embodiment of FIG. 1. In a similar manner, the invention is not limited to the stages or arrangement of layers in each stage shown in the specific non-limiting embodiments shown in FIGS. 3 and 4. In alternative embodiments to those in FIGS. 3 and 4, the multi-stage structure may comprise two, three or more stages. In such embodiments, each stage may have a different cross-section area, where the cross-sectional area is defined as being perpendicular to a direction from the substrate to the p-type contact layer. The cross-sectional area of each stage may decrease in a direction from the substrate to the p-type contact layer. The layers in the device 200, 300 may be distributed across the two or more stages in any suitable manner provided the p-type contact layer is in a different stage to the avalanche layer and the stage comprising the p-type contact layer has a smaller cross-sectional area than the stage comprising the avalanche layer. Additionally, the device or APD sub-assembly is not limited to the specific layers or order of layers described in relation to the embodiments of FIGS. 3 and 4.

As described above, in the embodiment shown in FIG. 3, the spacer layer may not comprise antimony. In an alternative embodiment, the spacer layer of the device 200 shown in FIG. 3 may comprise antimony. The spacer layer may comprise AlGaAsSb. In such embodiments, the device may be manufactured using dry etching to avoid oxidization of antimony caused by wet etching. The spacer layer may not comprise a first and a second portion. Rather, the spacer layer may have a uniform cross-sectional area in a direction perpendicular to the direction from the substrate to the p-type contact layer. Therefore, the transition from the first stage to the second stage may occur at the interface between the spacer layer and the charge sheet which is formed on the spacer layer. To manufacture a device having a spacer layer comprising antimony, a selective etchant may be used to remove the p-type contact layer and the layers between the spacer layer and the p-type contact layer without etching the spacer layer. As such, a uniform etch may be formed. Providing a spacer layer in this way may enable a thinner spacer layer to be used compared to a spacer layer having an upper portion and a lower portion. This may be advantageous when the device is to be used in high speed applications, such as telecommunications.

As described above, in the embodiment shown in FIG. 4, one or both of the first and second spacer layers may not comprise antimony. In alternative embodiments, the first and/or second spacer layers of the device 300 shown in FIG. 4 may comprise antimony. Each spacer layer may comprise AlGaAsSb. In such embodiments, the device may be manufactured using dry etching to avoid oxidization of antimony caused by wet etching. The first and second spacer layers may not comprise a first and a second portion. Rather, the first and second spacer layers may have a uniform cross-sectional area in a direction perpendicular to the direction from the substrate to the p-type contact layer. Therefore, the transition between the second and third stages may occur at the interface between the first spacer layer and the charge sheet which is formed on the first spacer layer. The transition between the third and first stages may occur at the interface between the second spacer layer and the graded cladding layer which is formed on the second spacer layer. As described above, to manufacture a device having a spacer layer comprising antimony, a selective etchant may be used to remove the p-type contact layer and the layers between the spacer layer and the p-type contact layer without etching the spacer layer. As such, a uniform etch may be formed. Providing a spacer layer in this way may enable a thinner spacer layer to be used compared to a spacer layer having an upper portion and a lower portion. This may be advantageous when the device is to be used in high speed applications, such as telecommunications.

In the specific non-limiting embodiments shown in FIGS. 5 and 8, the devices comprise the substrate having the first contact layer, the second cladding layer, the avalanche layer, the charge sheet, the second grading layer, the first grading layer, the absorption layer, the at least one stopper layer, the first cladding layer and the second contact layer layered in that order on the substrate. However, the device or APD sub-assembly is not limited to this order or combination of layers. Rather, any suitable combination and order of layers may be used.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. An avalanche photodiode (APD) sub-assembly comprising:
a substrate;
a n-type contact layer formed on the substrate;
a p-type contact layer;
an avalanche layer comprising antimony, the avalanche layer being disposed between the n-type contact layer and the p-type contact layer; and
an absorption layer disposed between the avalanche layer and the p-type contact layer;
wherein the APD sub-assembly has a multi-stage structure comprising a first stage and a second stage wherein the multi-stage structure comprises a stepped structure, wherein the first stage provides a first step and the second stage provides a second step;
wherein the first stage comprises the p-type contact layer and the second stage comprises the avalanche layer; and
wherein the first stage has a smaller cross-sectional area than the second stage, the cross-sectional area being perpendicular to a direction from the substrate to the p-type contact layer.

2. An APD sub-assembly according to claim 1, wherein the avalanche layer comprises AlGaAsSb, InAlAsSb or AlAsSb.

3. An APD sub-assembly according to claim 1, wherein the distance between a sidewall of the first stage and a sidewall of the second stage in a direction perpendicular to a direction from the substrate to the n-type contact layer is at least 15 μm.

4. An APD sub-assembly according to claim 1, wherein the avalanche layer has a thickness of from 100 nm to 1500 nm or from 300 nm to 1000 nm.

5. An APD sub-assembly according to claim 1, comprising a first spacer layer disposed between the avalanche layer and the p-type contact layer, the first spacer layer comprising a lower portion and an upper portion, wherein the upper portion has a smaller cross-sectional area than the lower portion, the cross-sectional area being perpendicular to the direction from the substrate to the p-type contact layer, and wherein the lower portion defines an upper boundary of the second stage.

6. An APD sub-assembly according to claim 5, wherein the first spacer layer comprises InP, InAlAs or AlGaAsSb.

7. An APD sub-assembly according to claim 5, wherein the first spacer layer has a thickness of between 250 nm and 4000nm or the first spacer layer has a thickness of between 50 nm and 200 nm.

8. An ADP sub-assembly according to claim 5, comprising a field control layer disposed between the avalanche layer and the first spacer layer, wherein the field control layer is p-doped.

9. An APD sub-assembly according to claim 8, wherein the field control layer comprises InAlAs, InGaAlAs, InP or InGaAsP.

10. An APD sub-assembly according to claim 5, wherein the absorption layer is disposed between the first spacer and the p-type contact layer.

11. An APD sub-assembly according to claim 1, wherein the absorption layer comprises InGaAs, InGaAlAs, InGaAsP, or an InGaAs/GaAsSb type-II superlattice.

12. An APD sub-assembly according to claim 10, comprising a transition portion disposed between the first spacer layer and the absorption layer; wherein the transition portion comprises a first grading layer of InAlGaAs or InGaAsP and a charge sheet disposed between the first grading layer and the avalanche layer;
wherein the charge sheet has a bandgap between the bandgap of the absorption layer and the bandgap of the avalanche layer.

13. An APD sub-assembly according to claim 12, wherein the charge sheet comprises InAlAs and/or wherein the charge sheet is p-doped

14. An APD sub-assembly according to claim 5, wherein the upper portion of the spacer layer resides within the first stage.

15. An APD sub-assembly according to claim 10, wherein the upper portion of the spacer layer resides within the first stage and the APD sub-assembly comprises a second grading layer disposed between the absorption layer and the p-type contact layer.

16. An APD sub-assembly according to claim 5, wherein the multi-stage stage structure comprises a third stage providing a third step, the third stage being disposed between the second stage and the first stage, the third stage having a smaller cross-sectional area than the first stage and a larger cross-sectional area than the second stage, the cross-sectional areas being perpendicular to the direction from the substrate to the p-type contact layer; and wherein the third stage comprises the upper portion of the first spacer layer and the absorption layer.

17. An APD sub-assembly according to claim 10, wherein the multi-stage stage structure comprises a third stage providing a third step, the third stage being disposed between the second stage and the first stage, the third stage having a smaller cross-sectional area than the first stage and a larger cross-sectional area than the second stage, the cross-sectional areas being perpendicular to the direction from the substrate to the p-type contact layer; and wherein the third stage comprises the upper portion of the first spacer layer and the absorption layer, and the APD-sub-assembly comprises a second spacer layer disposed between the absorption layer and the p-type contact layer, wherein the second spacer layer comprises an upper portion and a lower portion, wherein the upper portion has a smaller cross-sectional area than the lower portion the cross-sectional area being perpendicular to the direction from the substrate to the p-type contact layer; and wherein the third stage comprises the lower portion and the first stage comprises the upper portion.

18. An APD sub-assembly according to claim 17, wherein the second spacer layer comprises InP, InAlAs or AlGaAsSb and optionally wherein the APD sub-assembly according comprises a graded cladding layer within the first stage, disposed between the second spacer and the p-type contact, wherein the graded cladding layer has a graded doping which increases in a direction from the n-type contact layer to p-type contact layer from highly p-doped to intrinsic.

19-26. (canceled)

27. An APD sub-assembly according to claim 1, wherein the p-type contact layer comprises InGaAs, InP, InGaAsP, InAlAs or InGaAlAs and/or wherein the n-type contact layer comprises InGaAs, InP, InGaAsP, InAlAs or InGaAlAs and/or wherein the n-type contact layer is n-doped with silicon or tellurium.

28. An APD device comprising the APD sub-assembly according to claim 1 and, optionally, wherein the APD device comprises an electrode formed on each of the p-type contact layer and the n-type contact layer.
